(19) United States
(12) Patent Application Publication
(10) Pub. No.: US 2008/0012027 A1
(43) Pub. Date: Jan. 17, 2008

(54) LIGHT-EMITTING ELEMENT, LIGHT-EMITTING DEVICE, AND METHOD OF FABRICATING LIGHT-EMITTING ELEMENT

(75) Inventors: Tatsuya HONDA, Isehara (JP); Yuta ENDO, Atsugi (JP)

Correspondence Address: FISH & RICHARDSON P.C., P.O. BOX 1022, MINNEAPOLIS, MN, 55440-1022, US

(73) Assignee: SEMICONDUCTOR ENERGY LABORATORY CO., LTD., Atsugi-shi (JP)

(21) Appl. No.: 11/776,751

(22) Filed: Jul. 12, 2007

(30) Foreign Application Priority Data
Jul. 13, 2006 (JP) 2006-193289

(51) Int. Cl. H01L 33/00

(52) U.S. Cl. 257/79

(57) ABSTRACT

A method of fabricating a semiconductor device includes the steps of sequentially depositing a first electrode, a light-emitting layer containing zinc sulfide and manganese, and forming a second electrode; and applying thermal treatment to the light-emitting layer. A manganese atom in the zinc sulfide lattice is in a symmetry and nonequilibrium lattice position during film deposition, but has an atomic position which is stable in terms of energy after undergoing thermal treatment. A light-emitting device subjected to thermal treatment has higher luminance than a light-emitting device not subjected to thermal treatment. Further, while a light-emitting device not subjected to the thermal treatment emits only monochromatic light, a light-emitting device subjected to the thermal treatment can easily obtain white light. Therefore, a light-emitting device with low production cost can be fabricated.

### BACKGROUND OF THE INVENTION

1. Field of the Invention

The present invention relates to light-emitting materials of light-emitting elements utilizing electroluminescence. In addition, the invention relates to light-emitting devices and electronic devices having such light-emitting elements.

2. Description of the Related Art

In recent years, research and development of light-emitting elements utilizing electroluminescence (hereinafter also referred to as “EL elements”) have been actively conducted. The basic structure of a light-emitting element is such that a light-emissive substance is sandwiched between a pair of electrodes, and light emission from the light-emissive substance is obtained upon application of a voltage across the two electrodes.

Being of a self-luminous type, such a light-emitting element has advantages over liquid crystal displays in that it has wide viewing angles, high visibility, and high response speed as well as the feasibility of reduction in thickness and weight.

Light-emitting elements can be divided into organic EL elements which use an organic compound as a light-emissive substance and inorganic EL elements which use an inorganic compound as a light-emissive substance.

These organic and inorganic EL elements differ not only in their light-emitting materials but also in their light-emission mechanisms.

Inorganic EL elements are divided into a dispersion type and a thin-film type according to their element structures. The difference between the two EL elements is in that the former dispersion-type inorganic EL element includes a light-emitting layer in which a particulate light-emitting material is dispersed in a binder, while the latter thin-film-type light-emitting element has a light-emitting layer made of a thin film of a light-emitting material. Although the two light-emitting elements are different in the above points, they have a common characteristic in that both require electrons that are accelerated by a high electric field. As types of light-emission mechanisms, there are luminescence obtained by donor-acceptor recombination which utilizes a donor level and an acceptor level, and local luminescence which utilizes inner-shell electron transition of metal ions.

Between the two, the thin-film-type inorganic EL element has, as shown in FIG. 2, a double-insulator structure in which a light-emitting layer 1503 is sandwiched between insulating films (a first insulating film 1502 and a second insulating film 1504) which are further sandwiched between a pair of electrodes (a first electrode 1501 and a second electrode 1505). When a voltage is applied across the two electrodes (the first electrode 1501 and the second electrode 1505) from respective power supplies (a first power supply 1506 and a second power supply 1507), light emission can be obtained. For inorganic EL elements, the first insulating film 1502 and the second insulating film 1504 formed between the opposite electrodes are considered to be important elements. For example, in order to increase the luminance of inorganic EL elements, a technique of retaining an appropriate capacitance ratio between the first insulating film and the second insulating film has been devised (e.g., see Reference 1: Japanese Published Patent Application No. 2001-250691).

Further, in order to improve the reliability of inorganic EL elements, a method of forming the first insulating film 1502 and the second insulating film 1504 that are used as the dielectric films has been devised (e.g., see Reference 2: Japanese Published Patent Application No. 2004-311422).

### SUMMARY OF THE INVENTION

However, even when the insulating films sandwiched between the opposite electrodes have been improved, it has been difficult to obtain high reliability while maintaining a substantial luminance level. Therefore, it is an object of the invention to provide a light-emitting element having sufficient luminance and high reliability, and a light-emitting device using such a light-emitting element.

One aspect of the invention is a light-emitting element including a light-emitting layer. The light-emitting layer contains zinc sulfide and manganese, and has an emission spectrum in the wavelength range of 500 to 700 nm. The emission spectrum includes a first peak having a shorter wavelength than 580 nm and a second peak having a longer wavelength than 580 nm.

Another aspect of the invention is a light-emitting device including a light-emitting element and a driver circuit for controlling the emission of the light-emitting element. The light-emitting element includes a light-emitting layer which contains zinc sulfide and manganese and has an emission spectrum in the wavelength range of 500 to 700 nm. The emission spectrum includes a first peak having a shorter wavelength than 580 nm and a second peak having a longer wavelength than 580 nm;

Still another aspect of the invention is a method of fabricating a light-emitting element including the steps of forming a light-emitting layer which contains zinc sulfide and manganese and has an emission spectrum with one emission peak in the range of 500 to 700 nm; and applying thermal treatment to the light-emitting layer so that the emission spectrum with one emission peak is divided into a first peak having a shorter wavelength than 580 nm and a second peak having a longer wavelength than 580 nm.

It is the gist of the invention to, after formation of a light-emitting layer, change the symmetric property of an atomic position of an impurity element that is added into a base emission material. The fabrication method of the invention includes the steps of forming a light-emitting layer by mixing an impurity element into a base emission material, and providing energy to the light-emitting layer by applying treatment for inducing an atomic structural change of the impurity element, in order to change the symmetric property of the atomic position of the impurity element.

According to the invention, a light-emitting element which has increased luminance but has a reduced luminance decay rate over time can be provided. In particular, emission properties in the visible region can be stabilized. In addition, since the emission spectrum can be made broader and changed to an emission spectrum of a mixed color, such a light-emitting element can be used for various applications.

### BRIEF DESCRIPTION OF THE DRAWINGS

In the accompanying drawings:

FIG. 1 shows the EL spectrum of a light-emitting device of the invention;

FIG. 2 shows the structure of a conventional light-emitting device;

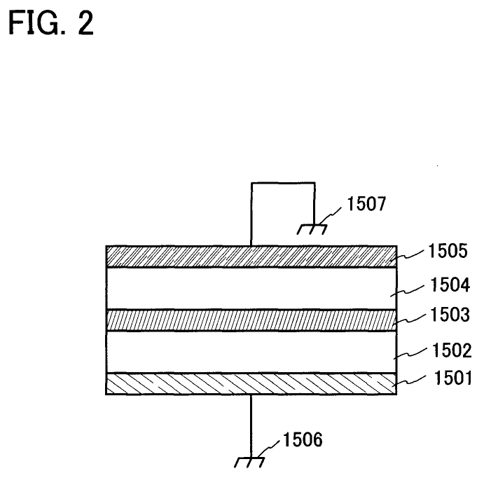

FIGS. 3A and 3B show the crystal states of ZnS:Mn;

FIG. 4 shows the structure of a light-emitting device of the invention;

FIG. 5 shows the paths of electronic excitation and relaxation;

FIGS. 6A and 6B are a perspective view and a cross-sectional view, respectively, of a light-emitting device of the invention;

FIGS. 7A and 7B are a top view and a cross-sectional view, respectively, of a light-emitting device of the invention;

FIGS. 8A to 8D illustrate electronic devices to which the invention is applied;

FIG. 9 illustrates an electronic device to which the invention is applied;

FIG. 10 shows the luminance decay rate of a light-emitting element;

FIGS. 11A to 11D show fabrication steps of a light-emitting device of the invention;

FIGS. 12A to 12C show fabrication steps of a light-emitting device of the invention;

FIGS. 13A and 13B show fabrication steps of a light-emitting device of the invention;

FIG. 14 shows a fabrication step of a light-emitting device of the invention;

FIGS. 15A and 15B show fabrication steps of a light-emitting device of the invention;

FIGS. 16A and 16B show light-emitting devices of the invention;

FIG. 17 shows a light-emitting device of the invention;

FIG. 18 shows a light-emitting device of the invention;

FIG. 19 shows a light-emitting device of the invention; and

FIGS. 20A and 20B show light-emitting devices of the invention.

### DETAILED DESCRIPTION OF THE INVENTION

Embodiment modes of the invention will be described below with reference to the accompanying drawings. Note that the invention is not limited to the following description, and it will be easily understood by those skilled in the art that various changes and modifications can be made without departing from the spirit and scope of the invention. Therefore, the invention should not be construed as being limited to the description in the following embodiment modes. Note that portions that are common or portions having similar functions in different drawings are denoted by the same reference numerals, and their repetitive description will be omitted.

### Embodiment Mode 1

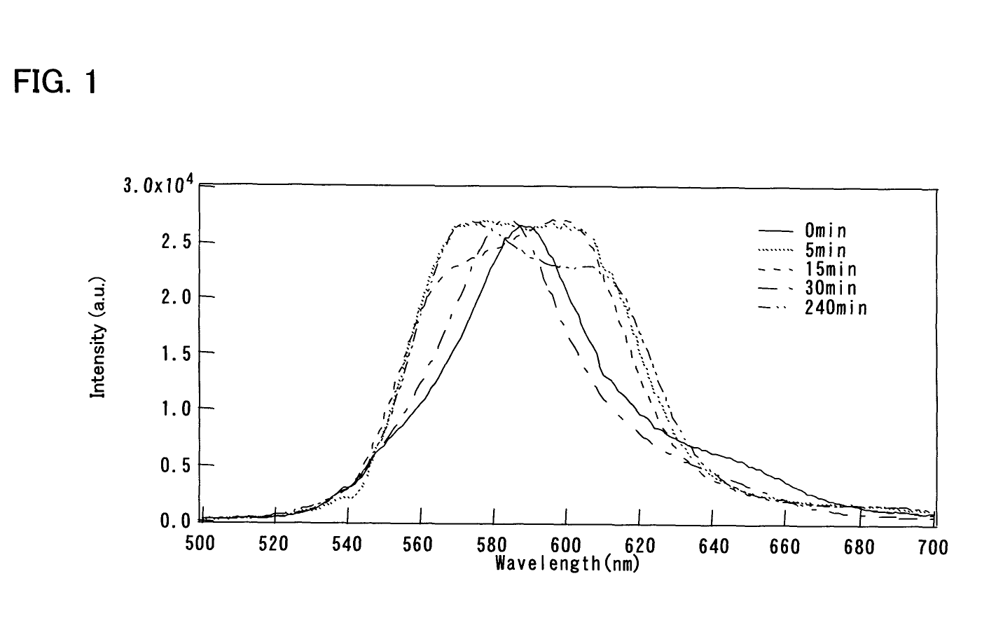

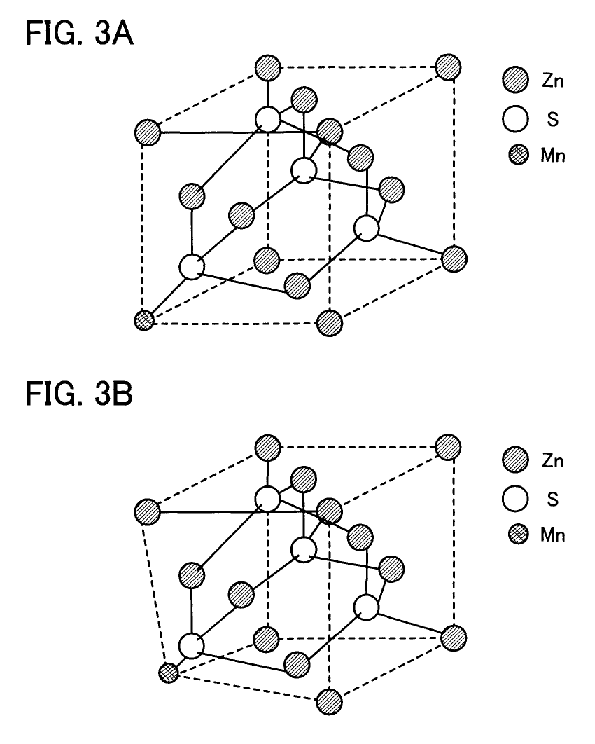

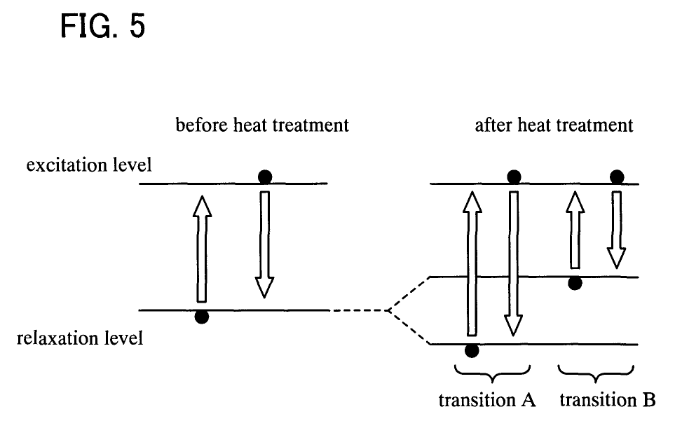

This embodiment mode will be described with reference to FIG. 1, FIGS. 3A and 3B, FIG. 4, FIG. 5, and FIG. 10.

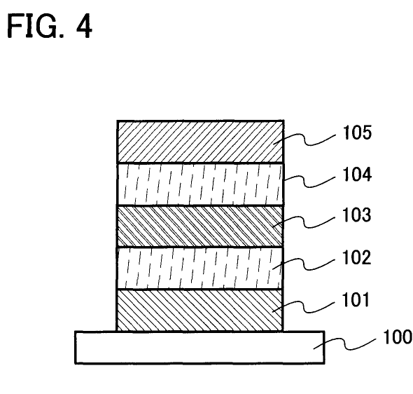

A light-emitting element of this embodiment mode includes, as shown in FIG. 4, a first electrode 101, a second electrode 105, a light-emitting layer 103 sandwiched between the first electrode 101 and the second electrode 105, a first dielectric layer 102 sandwiched between the first electrode 101 and the light-emitting layer 103, and a second dielectric layer 104 sandwiched between the light-emitting layer 103 and the second electrode 105, over a substrate 100.

Note that the structure of the light-emitting element is not limited to that shown in FIG. 4. For example, only one of the first dielectric layer 102 and the second dielectric layer 104 may be provided. In this embodiment mode, the first electrode 101 functions as an anode and the second electrode 105 functions as a cathode.

The substrate 100 is used as a support of the light-emitting element. The substrate 100 can be formed using, for example, glass, quartz, or the like. Besides, other materials can also be used as long as they can function as a support of the light-emitting element during its fabrication process.

The first electrode 101 and the second electrode 105 can be each formed using a metal, an alloy, an electrically conductive compound, or a mixture of them. Specifically, indium tin oxide (ITO), ITO containing silicon oxide (ITSO), indium zinc oxide (IZO), indium oxide containing tungsten oxide and zinc oxide (IWZO), and the like can be used.

Such conductive metal oxide films are generally formed by a sputtering method, an ion plating method, or the like. For example, indium zinc oxide (IZO) can be deposited by sputtering with a target in which 1 to 20 wt % zinc oxide is added to indium oxide. In addition, indium oxide containing tungsten oxide and zinc oxide (IWZO) can be deposited by sputtering with a target in which 0.5 to 5 wt % tungsten oxide and 0.1 to 1 wt % zinc oxide are added to indium oxide. Besides, aluminum (Al), silver (Ag), gold (Au), platinum (Pt), nickel (Ni), tungsten (W), chromium (Cr), molybdenum (Mo), iron (Fe), cobalt (Co), copper (Cu), palladium (Pd), nitride of metal materials (e.g., titanium nitride: TiN), and the like can also be used.

Note that when the first electrode 101 or the second electrode 105 is to be formed as a light-transmissive electrode, even a material with low transmittance of visible light can be used as long as it is deposited to a thickness of about 1 to 50 nm, preferably 5 to 20 nm. Note also that not only sputtering, but also vacuum deposition, CVD, or a sol-gel method can be used.

However, since light emission is extracted outside through the first electrode 101 or the second electrode 105, at least one of the first electrode 101 and the second electrode 105 should be formed with a light-transmissive material. In addition, it is preferable to select materials such that the first electrode 101 has a higher work function than the second electrode 105.

When both of the first electrode 101 and the second electrode 105 are formed using light-transmissive materials, a light-emitting device having the light-emitting element of this embodiment mode is completed as a dual emission light-emitting device. On the other hand, when one of the first electrode 101 and the second electrode 105 is formed using a reflective material, a light-emitting device having the light-emitting element of this embodiment mode is completed as a single emission (top emission or bottom emission) light-emitting device.

In this embodiment mode, a film of ITO containing silicon oxide (ITSO) is deposited as the first electrode 101 by a sputtering method. In addition, an aluminum film is deposited as the second electrode 105 by a sputtering method.

Materials which constitute the light-emitting layer 103 include an inorganic material such as sulfide which serves as a base material of the light-emitting layer, and an impurity element which serves as a luminescence center.

When zinc sulfide (ZnS) is used as a base material and manganese (Mn) is used as an impurity element, Zn of ZnS which is the base material is partially substituted by Mn which is the luminescence center.

In this embodiment mode, ZnS containing Mn (hereinafter also referred to as “ZnS:Mn”) is deposited to a thickness of 500 nm by a sputtering method using a target of ZnS which contains 0.5 wt % Mn and using an argon (Ar) gas as a sputtering gas.

Materials which constitute the dielectric layer 102 and the dielectric layer 104 are inorganic materials such as nitride and oxide. In this embodiment mode, each of the dielectric layers 102 and 104 is formed by depositing silicon nitride to a thickness of 200 nm by a sputtering method using silicon (Si) as a target and a nitrogen (N₂) gas as a sputtering gas.

After the formation of the dielectric layer 104, thermal treatment is applied. Here, dependence of the luminance of the EL element (ZnS:Mn) on the thermal treatment time is shown. After deposition of a ZnS:Mn film, thermal treatment at 600° C. is applied to the film while supplying a nitrogen (N₂) gas. During the thermal treatment, the EL spectrum of the deposited ZnS:Mn film was measured at the time points of 5 minutes, 15 minutes, 30 minutes, and 240 minutes. FIG. 1 shows the EL spectrum dependence on the thermal treatment time.

In FIG. 1, there is one yellow peak (588 nm) before the thermal treatment is applied (thermal treatment time of zero minute), whereas after five minutes have passed since the beginning of the thermal treatment, the luminescence peak of yellow is split into two peaks of green and orange. Further, after 240 minutes (four hours) have passed since the beginning of the thermal treatment, two luminescence peaks are observed likewise.

As one of the causes that the luminescence peak is split by thermal treatment, change in symmetric property of the atomic position of a Mn atom in a ZnS lattice can be considered.

Crystal structures of ZnS are categorized as a sphalerite structure (cubic crystal) and a wurtzite structure (hexagonal crystal). Generally, ZnS has a sphalerite structure. ZnS has a high ion bonding property, and Zn atoms and S atoms in the ZnS lattice are ionically bound to each other as Zn²⁺ and S²⁻, respectively.

Both a Zn atom and a Mn atom have 4S² outermost electrons. When Mn is added into ZnS, Zn in the ZnS lattice is substituted by the Mn atom, whereby the Mn atom is ionized (Mn²⁺).

The ionization energy of a Mn atom (171 kcal/mol) is lower than the ionization energy of a Zn atom (216 kcal/mol), and thus the Mn atom easily becomes a positive ion. Therefore, the bonding strength of Mn²⁺ to S²⁻ is higher than that of Zn²⁺ to S²⁻. Further, since an atomic radius of the Mn atom (0.117 nm) is shorter than that of the Zn atom (0.125 nm), the Mn atom can be displaced from the normal lattice position.

As per above, the Mn atom by which the Zn atom in the ZnS lattice has been substituted is stabilized in terms of energy, and is displaced from the normal lattice position in such a manner that it becomes far from the Zn atom while at the same time coming close to the S atom. During sputtering deposition, the Mn atom in the ZnS lattice is in a symmetry and nonequilibrium lattice position as shown in FIG. 3A, whereas after thermal treatment is applied and the Mn atom is stabilized in terms of energy, it loses a symmetric property. As a result, the crystal lattice is distorted as shown in FIG. 3B.

When the Mn atom receives energy that is generated by the distortion of the crystal lattice (a deformation potential), degeneracy of the orbital energy of the Mn atom is broken and split.

As a result, there arise two paths of electronic excitation and relaxation (i.e., Transition A and Transition B). For this reason, the luminescence peak can be considered to be split into two peaks.

In this manner, the fact that the luminescence peak is split into two peaks means the yellow monochromatic light changes to a mixed color of green and orange after the thermal treatment. According to this embodiment mode, monochromatic light can be easily changed to light of a mixed color. Therefore, white light can be easily produced.

Comparisons were made between the luminance of a light-emitting element which includes a light-emitting layer not subjected to thermal treatment and the luminance of a light-emitting element which includes a light-emitting layer subjected to thermal treatment (see Table 1). As a result, the light-emitting element which includes the light-emitting layer not subjected to thermal treatment had a luminance of 800 cd/m², while the light-emitting element which includes the light-emitting layer subjected to thermal treatment had a higher luminance of 1600 cd/m².

TABLE 1

| | Thermal Treatment | Thermal |
|---|---|---|
| | Not Applied | Treatment Applied |
| Luminance | 800 cd/m² | 1600 cd/m² |

Heating Temperature: 600° C.
Atmosphere: Nitrogen (N₂)

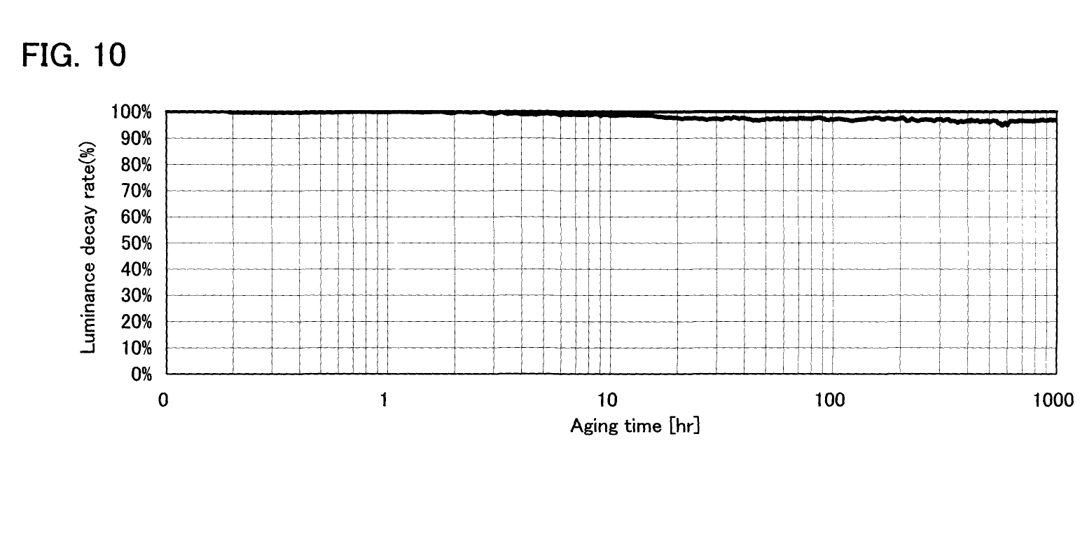

FIG. 10 shows the luminance decay rate of the light-emitting element which includes the light-emitting layer subjected to thermal treatment. As is evident from FIG. 10, the light-emitting element of the invention has quite a low luminance decay rate.

As per above, a light-emitting element which has increased luminance but has a reduced luminance decay rate over time can be provided. In particular, emission properties in the visible region can be stabilized. In addition, since the emission spectrum can be made broader and changed to an emission spectrum of a mixed color, such a light-emitting element can be used for various applications. Accordingly, a highly reliable and low-cost light-emitting device can be fabricated.

### Embodiment Mode 2

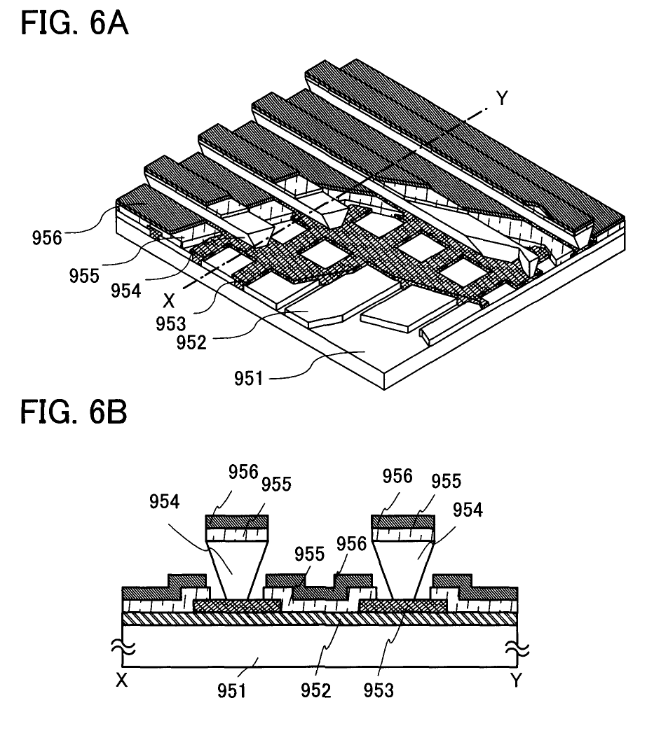

This embodiment mode will describe a light-emitting device having the light-emitting element of the invention, with reference to FIGS. 6A and 6B.

A light-emitting device shown in this embodiment mode is a passive matrix light-emitting device in which a light-emitting element is driven without providing a driving element such as a transistor over the same substrate as the light-emitting element. FIG. 6A is a perspective view of a passive matrix light-emitting device fabricated by applying the invention, and FIG. 6B is a partial cross-sectional view taken along line X-Y of FIG. 6A.

In FIGS. 6A and 6B, a layer 955 is provided between an electrode 952 and an electrode 956 over a substrate 951. Note that the layer 955 includes a light-emitting layer shown in Embodiment Mode 1 which is formed with a light-emitting material containing ZnS and Mn as a base material and a luminescence center, respectively.

The edge of the electrode 952 is covered with an insulating layer 953. A partition layer 954 is provided over the insulating layer 953. Sidewalls of the partition layer 954 slope so that a distance between one sidewall and the other sidewall becomes narrow toward a substrate surface. That is, a cross section of the partition layer 954 in the direction of a short side is trapezoidal, and a bottom base (a side expanding in the same direction as a plane direction of the insulating layer 953 and in contact with the insulating layer 953) is shorter than a top base (a side expanding in the same direction as the plane direction of the insulating layer 953 and not in contact with the insulating layer 953). The partition layer 954 provided in this manner can prevent the light-emitting element from being defective due to static electricity or the like. In addition, the use of the light-emitting element of the invention which operates at a low driving voltage can achieve low power consumption of the passive matrix light-emitting device. Further, providing the partition layer 954 having the shape shown in FIGS. 6A and 6B enable the layer 955 and the second electrode 956 to be formed in a self-aligned manner.

Although this embodiment mode has illustrated one structure of a light-emitting element, the invention is not limited to this. For example, a dielectric layer may be formed over the electrode, or the layer including a light-emitting layer may be formed with a stacked structure of a p-type semiconductor and an n-type semiconductor. Further, like a function-separated-type light-emitting element such as an organic EL element, not only a light-emitting layer, but also another functional layer which is in contact with the light-emitting layer may be provided. Such functional layer has a function of enhancing the orientation of the light-emitting layer as well as a function of a carrier injection layer or a carrier transporting layer.

According to this embodiment mode, a light-emitting element which has increased luminance but has a reduced luminance decay rate over time can be provided as in Embodiment Mode 1. In particular, emission properties in the visible region can be stabilized. In addition, since the emission spectrum can be made broader and changed to an emission spectrum of a mixed color, such a light-emitting element can be used for various applications.

Further, since the light-emitting device of the invention can easily produce light of a mixed color, white light can be easily obtained. Furthermore, since the luminance decay rate of the light-emitting element is low, a highly reliable light-emitting device can be provided.

### Embodiment Mode 3

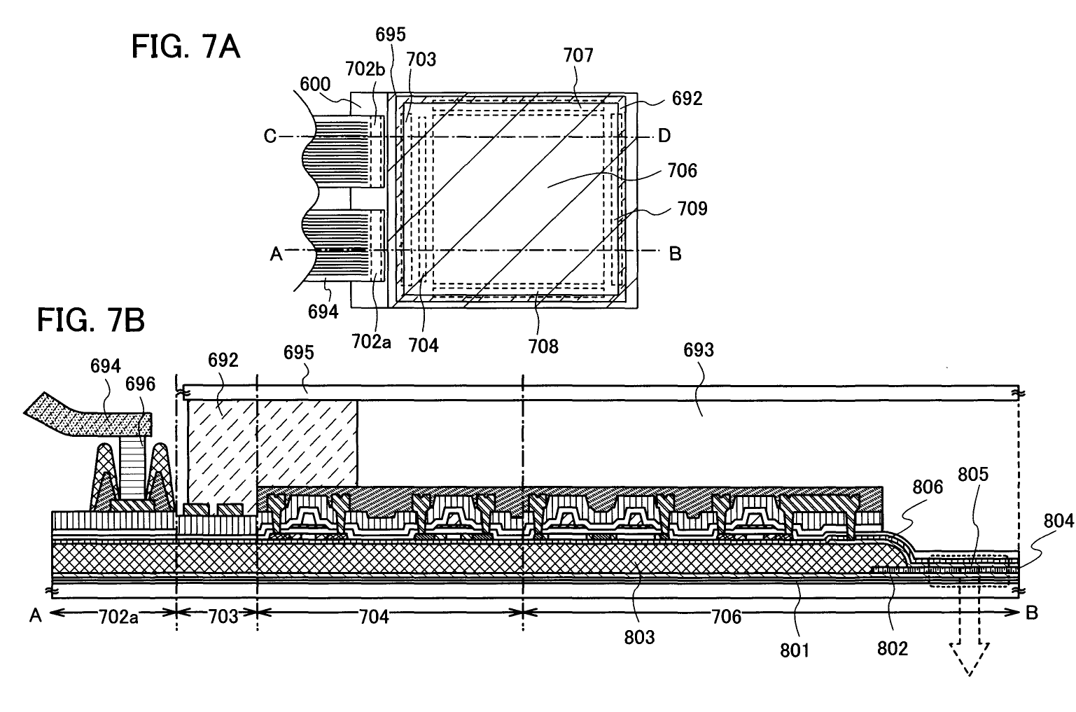

This embodiment mode will specifically describe a light-emitting device having light-emitting elements and a method of fabricating the light-emitting device, with reference to FIGS. 7A and 7B, FIGS. 11A to 11D, FIGS. 12A to 12C, FIGS. 13A and 13B, FIG. 14, and FIGS. 15A and 15B.

FIGS. 7A and 7B illustrate aspects of a light-emitting device of the invention. FIG. 7A is a top view of a light-emitting device of the invention and FIG. 7B is a cross-sectional view thereof. Note that a region indicated by line A-B in FIG. 7A corresponds to a region where an FPC 694 and wirings of transistors are electrically connected (hereinafter, this region is indicated by an external terminal connection region 702a). In addition, a region indicated by line C-D in FIG. 7A corresponds to a region where another FPC 694 and first electrode layers of light-emitting elements are electrically connected (hereinafter this region is indicated by an external terminal connection region 702b).

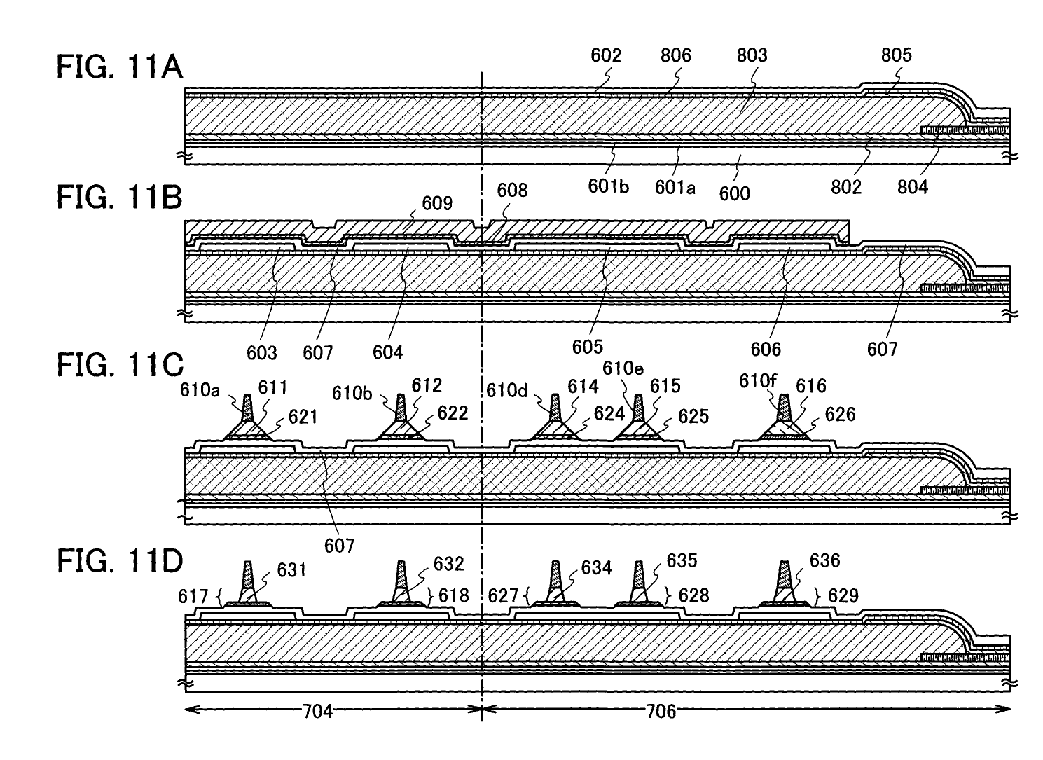

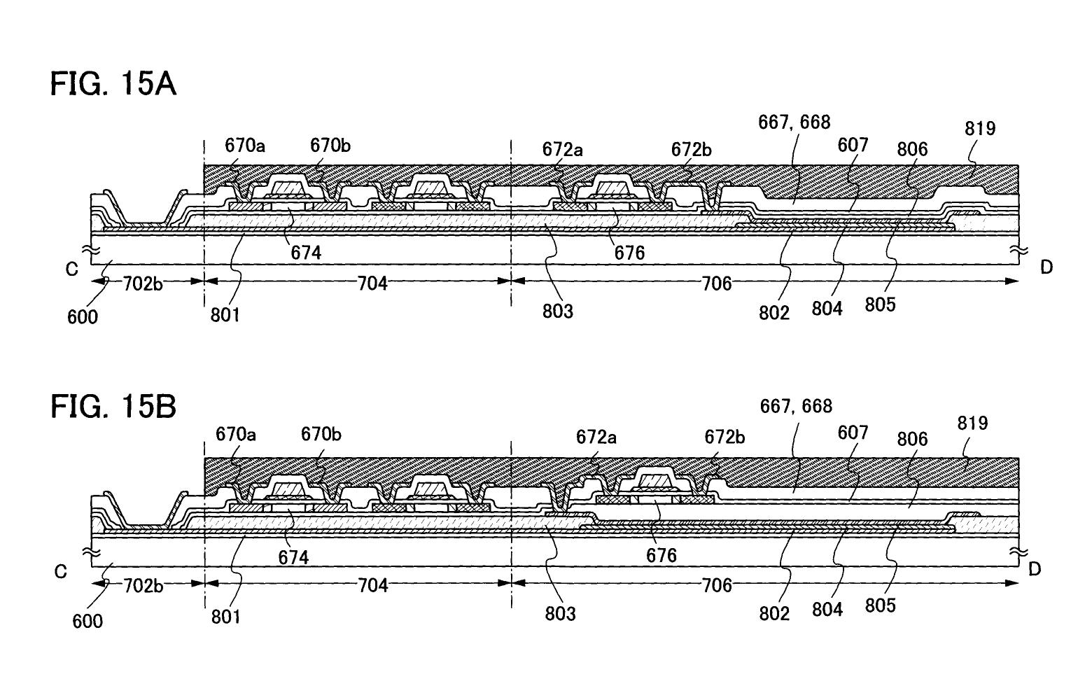

FIG. 7B is a cross-sectional view taken along line A-B of FIG. 7A. FIGS. 15A and 15B are cross-sectional views taken along line C-D of FIG. 7A. In addition, a method of fabricating the light-emitting device shown in FIG. 7B will be described with reference to FIGS. 11A to 11D, FIGS. 12A to 12C, FIGS. 13A and 13B, and FIG. 14.

Note that the main components of a thin film transistor (TFT) include a semiconductor layer, a gate insulating layer, and a gate electrode layer. In addition, the TFT also includes wiring layers connected to a source region and a drain region formed in the semiconductor layer. As typical structures of such a TF, the following are known: a top-gate TFT in which a semiconductor layer, a gate insulating layer, and a gate electrode layer are sequentially stacked over a substrate, and a bottom-gate TFT in which a gate electrode layer, a gate insulating layer, and a semiconductor layer are sequentially stacked over a substrate. Either of such structures can be applied to the invention.

A substrate 600 can be a glass substrate, a silicon substrate, or a metal substrate (e.g., stainless steel substrate) having an insulating film formed over its surface. When light emitted from the light-emitting element is extracted through the substrate, a light-transmissive substrate such as a glass substrate or a quartz substrate is preferably used. However, since a glass substrate will be deformed at a temperature higher than 800° C., a quartz substrate or a sapphire substrate is preferably used when the thermal treatment temperature of the light-emitting layer is higher than 800° C.

When light emitted from the light-emitting element is not extracted through the substrate but extracted to the side of TFT elements that will be formed in later steps, a substrate which does not transmit light can be used. Specifically, a ceramic substrate made of alumina, silicon nitride, or silicon carbide can be used.

In addition, in the case where light-emitting elements having TFT elements are formed over a substrate having a peeling layer over its surface, and the light-emitting elements are peeled off the substrate in a later step, the light transmissivity of the substrate is not particularly limited. Specifically, a substrate made of glass, quartz, alumina, silicon nitride, silicon carbide, ceramic, or the like can be used.

As base films formed over the substrate 600 having an insulating surface, a base film 601a is formed by depositing a silicon nitride film containing oxygen (also referred to as SiNO) to a thickness of 10 to 200 nm (preferably, 50 to 100 nm) and a base film 601b is formed by depositing a silicon oxide film containing nitrogen (also referred to as SiON) to a thickness of 50 to 200 nm (preferably, 100 to 150 nm), using a sputtering method, a PVD method (Physical Vapor Deposition) method, a low-pressure CVD (LPCVD) method, a CVD (Chemical Vapor Deposition) method such as plasma CVD, or the like.

In this embodiment mode, the base film 601a and the base film 601b are formed by a plasma CVD method.

For the base films, silicon oxide, silicon nitride, silicon oxide containing nitrogen, silicon nitride containing oxygen, or the like can be used. Further, either a single layer or a stacked structure of two or three layers can be employed. Note that in this specification, silicon oxide containing nitrogen is a substance which contains more oxygen than nitrogen. Likewise, silicon nitride containing oxygen is a substance which contains more nitrogen than oxygen. In this embodiment mode, a silicon nitride film containing oxygen is formed over the substrate to a thickness of 50 nm, using SiH₄, NH₃, N₂O, N₂, and H₂ as a reactive gas. Then, a silicon oxide film containing nitrogen is formed thereover to a thickness of 100 nm, using SiH₄ and N₂O as a reactive gas. Alternatively, the silicon nitride film containing oxygen may be formed to a thickness of 140 nm, and the silicon oxide film containing nitrogen stacked thereover may be formed to a thickness of 100 nm.

Next, a first electrode layer 802 is formed. When light emitted from the light-emitting element is extracted to the substrate side, the first electrode layer 802 may be formed using a transparent conductive film made of a light-transmissive conductive material such as indium tin oxide (ITO), indium zinc oxide (IZO), indium oxide containing tungsten oxide and zinc oxide (IWZO), indium oxide containing titanium oxide, ITO containing titanium oxide, or the like.

The first electrode layer 802 can be formed by a vapor deposition method, a sputtering method, or the like. When a sputtering method is used, gas containing moisture (moisture vapor: H₂O) or H₂ is preferably used. In this embodiment mode, a film of indium zinc oxide containing silicon oxide and tungsten oxide is formed as the first electrode layer 802 by a sputtering method using a target of indium zinc oxide containing tungsten oxide doped with silicon oxide and using gas containing moisture (H₂O) or H₂.

In this embodiment mode, indium zinc oxide containing tungsten oxide is doped with 10 wt % silicon oxide. The total thickness of the first electrode layer 802 is preferably in the range of 100 to 800 nm. In this embodiment mode, the first electrode layer 802 has a thickness of 185 nm.

In this embodiment mode, the first electrode layer 802 is formed with an argon (Ar) gas flow rate of 50 sccm, an oxygen (O₂) gas flow rate of 1.0 sccm, and a H₂O gas flow rate of 0.2 sccm. The gas containing moisture (moisture vapor: H₂O) used in the invention does not mean a gas containing a little amount of moisture due to a deposition method or a storage method, but means a gas which actively contains moisture as one of its main components. The flow rate of H₂O gas is preferably less than or equal to 0.5 sccm. The film of indium zinc oxide containing silicon oxide and tungsten oxide which is formed in this embodiment mode has high workability, and can be etched by weak-acid wet etching without leaving residues. When such a film is used for a pixel electrode of a display device, light emitted from a light-emitting element can be extracted efficiently. Further, a highly reliable display device which suppresses defects resulting from defective etching of the electrode can be fabricated.

Meanwhile, when light is extracted to only the side of the TFT elements, the first electrode layer 802 can be formed as a reflective electrode having a single layer or a plurality of layers made of highly heat-resistant metal films.

It is also possible to form the first electrode layer 802 by stacking a first conductive film with a thickness of 20 to 100 nm and a second conducive film with a thickness of 100 to 400 nm.

The conducive films may be formed with an element selected from among tantalum (Ta), tungsten (W), titanium (Ti), molybdenum (Mo), copper (Cu), chromium (Cr), and neodymium (Nd), or an alloy material or a compound material containing such an element as a main component.

It is also possible to use a semiconductor film typified by a polycrystalline silicon film doped with an impurity element such as phosphorus or an AgPdCu alloy.

Further, not only a single-layer structure, but also a two-layer structure or a three-layer structure may be employed.

Next, the first electrode layer 802 may be processed into a desired shape by a photolithography method using a resist mask (see FIG. 15A).

Then, the first electrode layer 802 can be etched into a desired tapered shape by an ICP (Inductively Coupled Plasma) etching method with appropriate control of the etching conditions (e.g., the amount of electric energy applied to a coiled electrode layer, the amount of electric energy applied to an electrode layer on the substrate side, and the electrode temperature on the substrate side). Note that an etching gas can be selected as appropriate from among a chlorine source gas typified by Cl₂, BCl₃, SiCl₄, or CCl₄; a fluorine source gas typified by CF₄, CF₅, SF₆, or NF₃; and O₂.

Next, a first dielectric layer is formed, followed by formation of the light-emitting layer 804. The methods of forming the first dielectric layer and the light-emitting element 804 are similar to those described in Embodiment Modes 1 and 2.

Materials which constitute the light-emitting layer 804 include an inorganic material such as sulfide which serves as a base material of the light-emitting layer, and an impurity element which serves as a luminescence center.

When zinc sulfide (ZnS) is used as a base material and manganese (Mn) is used as an impurity element, Zn of ZnS which is the base material is partially substituted by Mn which is the luminescence center.

The light-emitting layer 804 does not necessarily have to be a single layer of a base material layer which contains an impurity element serving as a luminescence center. For example, the light-emitting layer 804 may have a stacked structure of the above-described layer and a layer functioning as a carrier transporting layer. Specifically, the light-emitting layer 804 may be formed by stacking the above-described layer and a p-type semiconductor layer or an n-type semiconductor layer.

As a method of processing the light-emitting layer 804 into a desired fine shape, a conventional photolithography method of forming a photoresist pattern, followed by etching for removal of an unnecessary portion, or a liftoff method can be used.

After stacking the light-emitting layer 804 over the first electrode layer 802 as per above, a second dielectric layer is formed. Then, thermal treatment is applied at 500 to 800° C., for example 600° C. Accordingly, although the light-emitting layer 804 has an emission spectrum with one yellow peak (588 nm) before undergoing thermal treatment, after the thermal treatment is applied, the light-emitting layer 804 has an emission spectrum with two peaks: a first peak having a shorter wavelength than 580 nm and a second peak having a longer wavelength than 580 nm, i.e., peaks in the vicinity of green and orange. That is, the emission spectrum of the light-emitting layer 804 after undergoing the thermal treatment is distributed in the wavelength range of 500 to 700 nm, and has a first peak having a shorter wavelength than 580 nm and a second peak having a longer wavelength than 580 nm. Note that when the light-emitting layer 804 is heated at a high temperature, for example, at a temperature higher than or equal to 900° C., light emission cannot be observed. This can be considered due to a phenomenon that zinc sulfide is oxidized. Therefore, the thermal treatment temperature is acceptable as long as it is in the range of 500 to 800° C., for example, 600° C.

Next, an insulating layer 803 functioning as a partition is formed over the light-emitting layer. The insulating layer 803 functioning as the partition can be formed using a material selected from among silicon oxide, silicon nitride, silicon oxide containing nitrogen, silicon nitride containing oxygen, aluminum nitride (AlN), aluminum oxide containing nitrogen (AlON) in which the weight of oxygen is greater than nitrogen, aluminum nitride containing oxygen (AlNO) in which the weight of nitrogen is greater than that of oxygen, aluminum oxide, diamond-like carbon (DLC), a carbon film containing nitrogen (CN), PSG (phosphosilicate glass), borophosphosilicate glass (BPSG), an alumina film, and other inorganic insulating materials.

As a method of forming the insulating layer 803 functioning as the partition, dipping, spray coating, doctor knife, roll coater, curtain coater, knife coater, a CVD method, a vapor deposition method, or the like can be used. The insulating layer 803 functioning as the partition may also be formed by a droplet discharge method. In that case, a liquid material can be saved. As a further alternative, a method by which patterns can be selectively transferred or drawn like a droplet discharge method can be used. For example, a printing method (e.g., a pattern formation method such as screen printing or offset printing) or the like can be used.

Next, as shown in FIGS. 7B and 11A, an opening portion is formed in the insulating layer 803 functioning as the partition. Specifically, part of the insulating layer 803 functioning as the partition, which is located in the pixel portion, is etched. In addition, as shown in FIGS. 7B, 15A, and 15B, wide areas of the insulating layer 803 functioning as the partition should be etched in the external terminal connection regions 702a and 702b where the first electrode layer 802 is connected to a connection terminal.

Etching may be conducted by using a parallel-plate RIE apparatus or an ICP etching apparatus. Note that the etching time is preferably long enough to over-etch the wiring layer or the first electrode layer. By this over-etching, variations in thickness of the films over the substrate and variations in etching rate can be reduced. In this manner, opening portions are formed in the external terminal connection regions 702a and 702b.

Although this embodiment mode has illustrated the case where the insulating layer 803 functioning as the partition is etched with a mask having predetermined opening portions in the external terminal connection regions 702a and 702b and the pixel region 706, the invention is not limited to this. For example, since the opening portions of the connection regions have wide areas, the amount of etching is large. Such wide opening portions may be formed through a plurality of etching steps. Further, when an opening portion which is deeper than other opening portions is to be formed, a plurality of etching steps may be conducted likewise.

Next, a second electrode layer 805 is formed over the light-emitting layer 804. The second electrode layer 805 will be in contact with a source electrode or a drain electrode of a TFT which will be formed later.

A conductive film used as the second electrode layer 805 (also referred to as a pixel electrode layer) over the light-emitting layer 804 may be formed using an element selected from among tantalum (Ta), tungsten (W), titanium (Ti), molybdenum (Mo), aluminum (Al), copper (Cu), chromium (Cr), and neodymium (Nd), or an alloy material or a compound material containing such an element as a main component. Alternatively, it is also possible to use a semiconductor film typified by a polycrystalline silicon film doped with an impurity element such as phosphorus or an AgPdCu alloy.

Further, the structure of the second electrode layer 805 is not limited to a single layer, but a two-layer structure or a three-layer structure may also be employed.

When the second electrode layer 805 is formed with a reflective conductive film, light emitted from the light-emitting element is extracted to the substrate side. Meanwhile, when the second electrode layer 805 is formed with a transparent conductive film, light emitted from the light-emitting element is extracted to both of the substrate side and the sealing substrate side.

In this embodiment mode, tungsten (W) is formed to a thickness of 370 nm as the conducive film. Next, a resist mask is formed by a photolithography method, and the second electrode layer 805 is formed (see FIG. 11A).

Then, the second electrode layer 805 can be etched into a desired tapered shape by an ICP (Inductively Coupled Plasma) etching method with appropriate control of the etching conditions (e.g., the amount of electric energy applied to a coiled electrode layer, the amount of electric energy applied to an electrode layer on the substrate side, and the electrode temperature on the substrate side). Note that an etching gas can be selected as appropriate from among a chlorine source gas typified by Cl₂, BCl₃, SiCl₄, or CCl₄; a fluorine source gas typified by CF₄, CF₅, SF₆, or NF₃; and O₂.

Next, a first interlayer insulating layer 806 is formed. The first interlayer insulating layer 806 can be formed using a material selected from among silicon oxide, silicon nitride, silicon oxide containing nitrogen, silicon nitride containing oxygen, aluminum nitride (AlN), aluminum oxide containing nitrogen (AlON) in which the weight of oxygen is greater than that of nitrogen, aluminum nitride containing oxygen (AlNO) in which the weight of nitrogen is greater than that of oxygen, aluminum oxide, diamond-like carbon (DLC), a carbon film containing nitrogen (CN), PSG (phosphosilicate glass), borophosphosilicate glass (BPSG), an alumina film, and other inorganic insulating materials.

As a method of forming the first interlayer insulating layer 806, dipping, spray coating, doctor knife, roll coater, curtain coater, knife coater, a CVD method, a vapor deposition method, or the like can be used. The first interlayer insulating layer 806 may also be formed by a droplet discharge method. In that case, a liquid material can be saved. As a further alternative, a method by which patterns can be selectively transferred or drawn like a droplet discharge method can be used. For example, a printing method (e.g., a pattern formation method such as screen printing or offset printing) or the like can be used.

Next, as shown in FIGS. 7B and 11B, an opening portion is formed above the first interlayer insulating layer 806. Specifically, wide areas of the first interlayer insulating layer 806, which are located in a connection region (not shown), a wiring region 703, the external terminal connection region 702a, and the like, should be etched. However, the area of the opening portion in the pixel region 706 is much smaller than those of the connection region and the like. Therefore, providing a photolithography step for formation of an opening portion in the pixel region 706 and another photolithography step for formation of an opening portion in the connection region can further increase a margin of the etching conditions. As a result, yield can be improved. In addition, widening the margin of the etching conditions enables highly precise formation of contact holes in the pixel region 706.

Specifically, a wide opening portion is formed in the first interlayer insulating layer 806 which is provided in the connection region, the wiring region 703, the external terminal connection region 702a, and part of a peripheral driver circuit region 704. Therefore, a mask is formed so as to cover the insulating layer 806 in the pixel region 706, part of the connection region, and part of the peripheral driver circuit region 704. Etching may be conducted by using a parallel-plate RIE apparatus or an ICP etching apparatus. Note that the etching time is preferably long enough to over-etch the second electrode layer or the insulating layer functioning as the partition. By this over-etching, variations in thickness of the films over the substrate and variations in etching rate can be reduced. In this manner, an opening portion is formed in the external terminal connection region 702a.

Next, a semiconductor film is formed over the first interlayer insulating layer 806. The semiconductor film may be deposited to a thickness of 25 to 200 nm (preferably, 30 to 150 nm) by a sputtering method, a LPCVD method, a plasma CVD method, or the like. A material for forming the semiconductor film can be an amorphous semiconductor (hereinafter also referred to as “AS”) formed by a sputtering method or a vapor phase growth method using a semiconductor material gas typified by silane or germane, a polycrystalline semiconductor formed by crystallizing the amorphous semiconductor by using optical energy or thermal energy, a semi-amorphous semiconductor (also referred to as microcrystal and hereinafter also referred to as “SAS”), or the like.

SAS is a semiconductor having an intermediate structure between amorphous and crystalline (including single-crystalline and polycrystalline) structures and a third state which is stable in terms of free energy. Moreover, SAS includes a crystalline region with short-range order and lattice distortion. At least part of the film includes a crystalline region of 0.5 to 20 nm. When SAS contains silicon as a main component, Raman spectrum shifts to a wave number side lower than 520 cm⁻¹. Diffraction peaks of (111) and (220) which are thought to be derived from a silicon crystal lattice are observed by X-ray diffraction. At least 1 atomic % hydrogen or halogen is contained in SAS in order to saturate dangling bonds.

SAS is formed by glow discharge decomposition (plasma CVD) of a gas containing silicon. As the gas containing silicon, SiH₄ as well as Si₂H₆, SiH₂Cl₂, SiHCl₃, SiCl₄, SiF₄, and the like can be used. Further, F₂ and GeF₄ may be mixed therein. The gas containing silicon may be diluted with H₂, or with H₂ and one or more of rare gas elements selected from among He, Ar, Kr, and Ne. The dilution ratio is in the range of 2 to 1000 times, pressure is in the range of 0.1 to 133 Pa, and power supply frequency is 1 to 120 MHz, preferably, 13 to 60 MHz. The substrate heating temperature is preferably lower than or equal to 300° C., and a substrate heating temperature of 100 to 200° C. is also possible.

As impurity elements which are introduced during the film deposition, impurities which derive from the atmospheric components such as oxygen, nitrogen, and carbon are preferably contained in the film at a concentration of not more than 1×10²⁰ cm⁻³. In particular, the concentration of oxygen is preferably not more than 5×10¹⁹ cm⁻³, more preferably, not more than 1×10¹⁹ cm⁻³. In addition, when a rare gas element such as helium, argon, krypton, or neon is mixed into the film to promote lattice distortion, excellent SAS with increased stability can be obtained. Alternatively, a semiconductor film may obtained by sequentially stacking an SAS layer which is formed using a fluorine source gas and another SAS layer which is formed using a hydrogen source gas.

It is preferable that the semiconductor film be a crystalline semiconductor film obtained by crystallizing an amorphous semiconductor film by laser irradiation.

In laser crystallization, a solid-state laser capable of continuous wave (CW) oscillation is used, and a laser beam with the second to fourth harmonics of a fundamental wave is used, whereby crystals with a large grain size can be obtained. For example, a second harmonic (532 nm) or a third harmonic (355 nm) of a Nd:YVO₄ laser (a fundamental wave of 1064 nm) is preferably used. Specifically, a laser beam emitted from a CW YVO₄ laser is converted into a harmonic with a non-linear optical element, whereby a laser beam with an output of a few watts or higher is obtained. Then, the laser beam is preferably formed into a rectangular shape or an elliptical shape at an irradiation surface by optics to irradiate the semiconductor film. At this time, an energy density of about 0.001 to 100 MW/cm² (preferably 0.1 to 10 MW/cm²) is required. Then, the semiconductor film is preferably irradiated with the laser beam at a scan rate of about 0.5 to 2000 cm/sec (preferably, 10 to 200 cm/sec).

The laser beam preferably has a linear shape. As a result, throughput can be improved. Further, the laser beam is preferably controlled to enter the semiconductor film at an incident angle of θ (0<θ<90 degrees) in order to prevent interference of laser beams.

By scanning such laser and a semiconductor film relative to each other, laser irradiation can be realized. Further, a marker may be formed to overlap beams with high accuracy and control the positions to start and finish laser irradiation. The marker may be formed on the substrate at the same time as the amorphous semiconductor film.

As the laser, a CW or pulsed gas laser, solid-state laser, a copper vapor laser, a gold vapor laser, or the like can be used. Examples of gas lasers include an excimer laser, an Ar laser, a Kr laser, a He—Cd laser, and the like. Examples of solid-state lasers include a YAG laser, a YVO₄ laser, a YLF laser, a YAlO₃ laser, a Y₂O₃ laser, a glass laser, a ruby laser, an alexandrite laser, a Ti:sapphire laser, and the like.

Alternatively, laser crystallization may be performed using pulsed laser beams with a repetition rate of 0.5 MHz or higher, which is much higher than the repetition rate of commonly used laser beams (several tens to several hundreds of Hz). It is said that it takes several tens to several hundreds of nanoseconds to completely solidify a semiconductor film once it is irradiated with a pulsed laser beam. Accordingly, when adopting pulsed laser beams with a repetition rate of 0.5 MHz or higher, a semiconductor film melted by a laser beam can be irradiated with the next pulsed laser beam before being solidified. Thus, the interface between the solid phase and the liquid phase of the semiconductor film can be continuously moved, and thus a semiconductor film with crystal grains that are continuously grown in the scan direction can be obtained. Specifically, it is possible to form an aggregation of crystal grains each having a width of 10 to 30 μm in the scan direction and a width of about 1 to 5 μm in a direction perpendicular to the scan direction. By forming such single crystal grains extending long in the scan direction, a semiconductor film having few crystal grain boundaries at least in the channel direction of the thin film transistor can be formed.

It is also possible to irradiate the semiconductor film with laser beams in an inert gas atmosphere such as a rare gas or a nitrogen gas. Accordingly, roughness of the semiconductor surface caused by laser irradiation can be suppressed, and variations in the threshold voltage of thin film transistors caused by variations in interface state density can also be suppressed.

Next, the crystalline semiconductor film 602 is processed into a desired shape using a mask. In this embodiment mode, an oxide film formed on the crystalline semiconductor film 602 is removed, and then a new oxide film is formed again. Then, a photolithography method using a photomask and etching treatment are applied to form semiconductor layers 603, 604, 605, and 606.

Etching treatment may be conducted either by plasma etching (dry etching) or by wet etching. Plasma etching is more suitable for processing a large-area substrate. As an etching gas, a fluorine source gas such as CF₄ or NF₃ or a chlorine source gas such as Cl₂ or BCl₃ may be used, and an inert gas such as He or Ar may also be added into the etching gas as appropriate. Further, when etching treatment is conducted by atmospheric discharge plasma, local discharge processing becomes possible; therefore, there is no need to form a mask layer over the entire surface of the substrate.

In the invention, conductive layers for forming wiring layers or electrode layers and mask layers for forming predetermined patterns may also be formed by a method by which patterns can be selectively formed like a droplet discharge method. A droplet discharge (ejection) method (which is also called an ink-jet method depending on methods) is a method capable forming a predetermined pattern (e.g., a conductive layer or an insulating layer) by selectively discharging (ejecting) droplets of a composition that has been premixed for a specific purpose. In this case, treatment for controlling the wettability or adhesiveness may be applied to a region in which the object layer is formed. In addition, another method by which patterns can be selectively transferred or drawn can be used. For example, a printing method (e.g., a pattern formation method such as screen printing or offset printing) or the like can also be used.

A mask used in this embodiment mode is formed with a resin material such as an epoxy rein, an acrylic rein, a phenol resin, a novolac resin, a melamine resin, or a urethane resin. Further, it is also possible to use an organic material such as benzocyclobutene, parylene, fluorinated arylene ether, or light-transmissive polyimide, a compound material formed by polymerization of siloxane polymers and the like, a composition material containing water-soluble homopolymers and water-soluble copolymers, and the like. Alternatively, a commercial resist material including a photosensitive agent can be used. For example, a positive resist or a negative resist can be used. In using any of the above-described materials in conducting a droplet discharge method, the surface tension and viscosity of the materials are appropriately controlled by adjusting the concentration of a solvent or by adding a surfactant or the like.

The oxide films on the semiconductor layers 603 to 606 are removed, and a gate insulating layer 607 which covers the semiconductor layers 603, 604, 605, and 606 is formed. The gate insulating layer 607 is formed by depositing an insulating film containing silicon to a thickness of 10 to 150 nm by a plasma CVD method or a sputtering method.

It is acceptable as long as the gate insulating layer 607 is formed with a material such as a silicon oxide material or a silicon nitride material typified by silicon nitride, silicon oxide, silicon oxide containing nitrogen, or silicon nitride containing oxygen. Further, the gate insulating layer 607 may be formed to have either a stacked structure or a single-layer structure. Alternatively, the gate insulating layer 607 may be formed to have a three-layer structure of a silicon nitride film, a silicon oxide film, and a silicon nitride film, a single layer of a silicon oxide film containing nitrogen, or a two-layer structure of the above-described materials. Preferably, a silicon nitride film having a dense film quality is used. Further, a thin silicon oxide film with a thickness of 1 to 100 nm, preferably 1 to 10 nm, or more preferably 2 to 5 nm may be formed between the semiconductor layers and the gate insulating layer. Such a thin silicon oxide film may be formed by oxidizing the surface of a semiconductor region by a GRTA method, a LRTA method, or the like, thereby forming a thermally oxidized film. Note that in order to form a dense insulating film with little gate leakage current at a low deposition temperature, it is preferable to mix a rare gas element such as argon into a reactive gas so that the rare gas element can be mixed into the insulating film to be formed. In this embodiment mode, a silicon oxide film containing nitrogen is formed to a thickness of 115 nm as the gate insulating layer 607.

Next, a first conductive film 608 with a thickness of 20 to 100 nm and a second conductive film 609 with a thickness of 100 to 400 nm are stacked as gate electrode layers over the gate insulating layer 607 (see FIG. 11B). The first conductive film 608 and the second conductive film 609 can be formed by a sputtering method, a vapor deposition method, a CVD method, or the like. The first conductive film 608 and the second conductive film 609 may be formed using an element selected from among tantalum (Ta), tungsten (W), titanium (Ti), molybdenum (Mo), aluminum (Al), copper (Cu), chromium (Cr), and neodymium (Nd), or an alloy material or a compound material containing such an element as a main component. Alternatively, the first conductive film 608 and the second conductive film 609 may be formed using a semiconductor film typified by a polycrystalline silicon film doped with an impurity element such as phosphorus or an AgPdCu alloy. Further, the structure of the first conductive film 608 and the second conductive film 609 is not limited to a two-layer structure, but a three-layer structure may also be employed, for example, such that a tungsten film with a thickness of 50 nm, an aluminum-silicon (Al—Si) alloy film with a thickness of 500 nm, and a titanium nitride film with a thickness of 30 nm are sequentially stacked as the first to third conductive films. Further, when adopting a three-layer structure, the tungsten film used for the first conductive film may be replaced with a tungsten nitride film, the aluminum-silicon (Al—Si) alloy film used for the second conductive film may be replaced with an aluminum-titanium (Al—Ti) alloy film, and the titanium nitride film used for the third conductive film may be replaced with a titanium film. Furthermore, a single-layer structure may also be used. In this embodiment mode, tantalum nitride (TaN) is deposited to a thickness of 30 nm as the first conductive film 608 and tungsten (W) is deposited to a thickness of 370 nm as the second conductive film 609.

Next, resist masks 610a, 610b, 610d, 610e, and 610f are formed by a photolithography method, and the first conductive film 608 and the second conductive film 609 are processed into desired shapes. As a result, first gate electrode layers 621, 622, 624, 625, and 626 and conductive layers 611, 612, 614, 615, and 616 are formed (see FIG. 11C).

Then, the first gate electrode layers 621, 622, 624, 625, and 626 and the conductive layers 611, 612, 614, 615, and 616 can be etched into desired tapered shapes by an ICP (Inductively Coupled Plasma) etching method with appropriate control of the etching conditions (e.g., the amount of electric energy applied to a coiled electrode layer, the amount of electric energy applied to an electrode layer on the substrate side, and the electrode temperature on the substrate side). In addition, angles and the like of the tapered shapes may also be controlled by the shapes of the masks 610a, 610b, 610d, 610e, and 610f. Note that an etching gas can be selected as appropriate from among a chlorine source gas typified by Cl₂, BCl₃, SiCl₄, or CCl₄; a fluorine source gas typified by CF₄, CF₅, SF₆, or NF₃; and O₂. In this embodiment mode, the second conductive film 609 is etched with an etching gas containing CF₅, Cl₂, O₂, and the like, and the first conductive film 608 is consecutively etched with an etching gas containing CF₅ and Cl₂.

Next, the conductive layers 611, 612, 614, 615, and 616 are processed into desired shapes by using the masks 610a, 610b, 610d, 610e, and 610f. At this time, the conductive layers are etched under the condition of high etching selectivity (a high ratio of the etching rate of the second conductive film 609 for forming the conductive layers to the etching rate of the first conductive film 608 for forming the first gate electrode layers). By this etching, the conductive layers 611, 612, 614, 615, and 616 are etched, whereby second gate electrode layers 631, 632, 634, 635, and 636 are formed.

In this embodiment mode, the second gate electrode layers are also tapered. Taper angles of the second gate electrode layers are larger than those of the first gate electrode layers 621, 622, 624, 625, and 626. Note that a taper angle means an angle of the side surface of the conducive layer (each of the first gate electrode layers and the second gate electrode layers) with respect to the bottom surface thereof. Accordingly, when the taper angle is set large, e.g., 90 degrees, the conductive layer has a perpendicular side surface. In this embodiment mode, Cl₂, SF₆, and O₂ are used as the etching gas for formation of the second gate electrode layers.

In this embodiment mode, each of the first gate electrode layers, the conductive layers, and the second gate electrode layers is formed to be tapered; therefore, both of the two gate electrode layers are tapered. However, the invention is not limited to this. For example, one of the gate electrode layers may be tapered while the other gate electrode layer may have a perpendicular side surface by anisotropic etching. In addition, the taper angle of each stacked gate electrode layer may be either the same or different from one another as in this embodiment mode. When each gate electrode layer is tapered, the gate electrode layer can be tightly covered with a film stacked thereover. Therefore, defects can be reduced and reliability can be improved.

Through the above-described steps, a gate electrode layer 617 having the first gate electrode layer 621 and the second gate electrode layer 631, and a gate electrode layer 618 having the first gate electrode layer 622 and the second gate electrode layer 632 can be formed in the peripheral driver circuit region 704; and a gate electrode layer 627 having the first gate electrode layer 624 and the second gate electrode layer 634, a gate electrode layer 628 having the first gate electrode layer 625 and the second gate electrode layer 635, and a gate electrode layer 629 having the first gate electrode layer 626 and the second gate electrode layer 636 can be formed in the pixel region 706 (see FIG. 11D). Although dry etching is conducted for the formation of the gate electrode layers in this embodiment mode, wet etching may also be used.

The gate insulating layer 607 may be slightly etched by the etching step for formation of the gate electrode layers. In that case, the gate insulating layer 607 has a reduced thickness.

When the gate electrode layers are formed to have narrow width, thin film transistors capable of high-speed operation can be formed. Two methods of forming a gate electrode layer having a narrow width in the channel direction will be described below.

The first method includes the steps of forming a mask of a gate electrode layer and reducing the width of the mask by etching, ashing, or the like, thereby forming a mask with a narrow width. By using a mask which has been processed into a narrow width, a gate electrode layer can also be formed into a narrow width.

The second method includes the steps of forming a normal mask, forming a gate electrode layer using the mask, and reducing the width of the gate electrode layer by side etching. As a result, a gate electrode layer with a narrow width can be obtained. Through the above-described steps, a thin film transistor with a short channel length can be formed, and also a thin film transistor capable of high-speed operation can be formed.

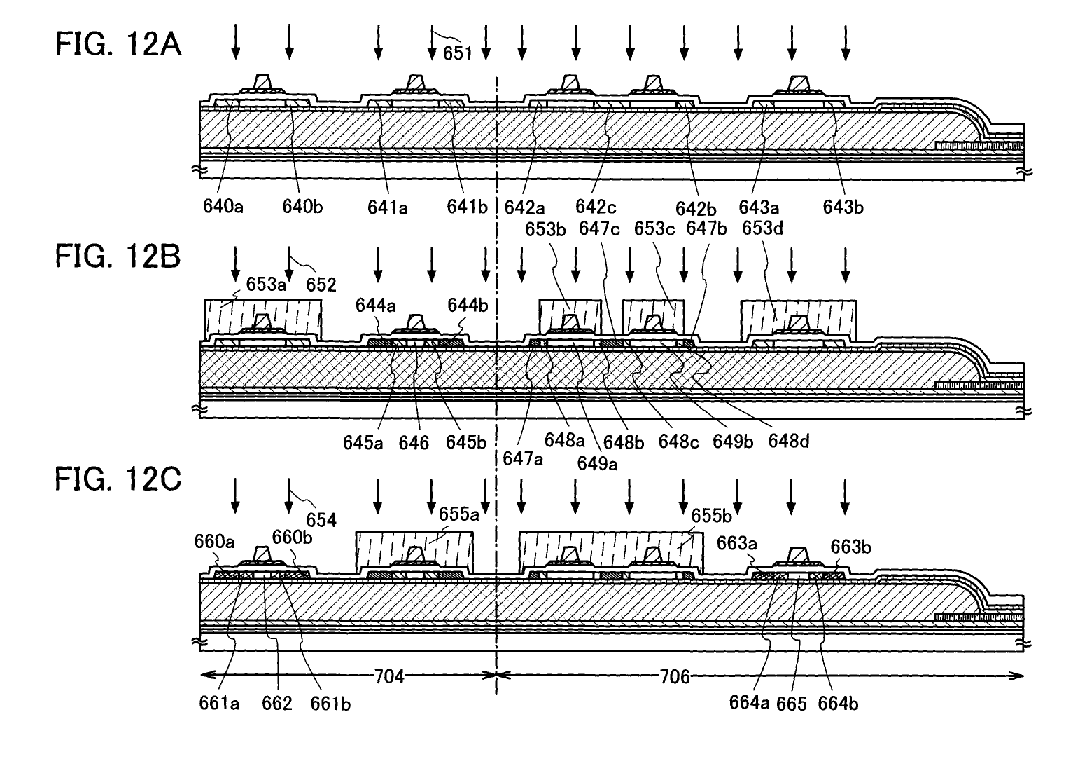

Next, the masks 610a, 610b, 610d, 610e, and 610f are removed, and the semiconductor layers are doped with an n-type impurity element 651, using the gate electrode layers 617, 618, 627, 628, and 629 as masks. Thus, first n-type impurity regions 640a, 640b, 641a, 641b, 642a, 642b, 642c, 643a, and 643b are formed (see FIG. 12A).

In this embodiment mode, doping is conducted by using phosphine (PH₃) as a doping gas containing an impurity element (the doping gas is obtained by diluting PH₃ with hydrogen (H₂); the percentage of PH₃ in the gas is 5%) under such conditions that the gas flow rate is 80 sccm, beam current is 54 μA/cm, acceleration voltage is 50 kV, and dosage is 7.0×10¹³ ions/cm². Here, doping is conducted such that each of the first n-type impurity regions 640a, 640b, 641a, 641b, 642a, 642b, 642c, 643a, and 643b contains the n-type impurity element at a concentration of about 1×10¹⁷ to 5×10¹⁸/cm³. In this embodiment mode, phosphorus (P) is used as the n-type impurity element.

In this embodiment mode, the impurity region which overlaps with the gate electrode layer with the gate insulating layer interposed therebetween is called a Lov region, while the impurity region which does not overlap with the gate electrode layer with the gate insulating layer interposed therebetween is called a Loff region. In FIGS. 12A to 12C, the impurity regions are indicated by hatching on a white background. This does not mean that the white background portion is not doped with an impurity element, but is shown so that it will be intuitively understood that the concentration distribution of the impurity element in the region reflects mask or doping conditions. Note that the same can be said for the other drawings in this specification.

Next, masks 653a to 653d which cover the semiconductor layer 603, part of the semiconductor layer 605, and the semiconductor layer 606 are formed. Then, the semiconductor layers are doped with an n-type impurity element 652 by using the masks 653a to 653d and the second gate electrode layer 632 as masks. Thus, second n-type impurity regions 644a and 644b, third n-type impurity regions 645a and 645b, second n-type impurity regions 647a, 647b, and 647c, and third n-type impurity regions 648a, 648b, 648c, and 648d are formed.

In this embodiment mode, doping is conducted by using PH₃ as a doping gas containing an impurity element (the doping gas is obtained by diluting PH₃ with hydrogen (H₂); the percentage of PH₃ in the gas is 5%) under such conditions that the gas flow rate is 80 sccm, beam current is 540 μA/cm, acceleration voltage is 70 kV, and dosage is 5.0×10¹⁵ ions/cm². Here, doping is conducted such that each of the second n-type impurity regions 644a and 644b contains the n-type impurity element at a concentration of about 5×10¹⁹ to 5×10²⁰/cm³. The third n-type impurity regions 645a and 645b are formed so as to contain the n-type impurity element at about the same concentration as or at a slightly higher concentration than the third n-type impurity regions 648a to 648d. In addition, a channel formation region 646 is formed in the semiconductor layer 604, and channel formation regions 649a and 649b are formed in the semiconductor layer 605.

The second n-type impurity regions 644a, 644b, 647a, 647b, and 647c are n-type high-concentration impurity regions and function as source regions or drain regions. On the other hand, the third n-type impurity regions 645a, 645b, 648a, 648b, 648c, and 648d are n-type low-concentration impurity regions and function as LDD (Lightly Doped Drain) regions.

The third n-type impurity regions 645a and 645b that are covered with the first gate electrode layer 622 with the gate insulating layer 607 interposed therebetween are Lov regions, which can alleviate an electric field in the vicinity of the drain and can suppress hot-carrier degradation. As a result, a thin film transistor capable of high-speed operation can be formed. On the other hand, the third n-type impurity regions 648a, 648b, 648c, and 648d that are not covered with the gate electrode layer 627 or the gate electrode layer 628 are Loff regions, which can alleviate an electric field in the vicinity of the drain and can prevent degradation due to hot-carrier injection as well as reducing off-current. As a result, a highly reliable and low-power-consumption semiconductor device can be fabricated.

Next, the masks 653a to 653d are removed, and masks 655a and 655b which cover the semiconductor layers 604 and 605, respectively are formed. Then, the semiconductor layers are doped with a p-type impurity element 654 by using the masks 655a and 655b and the gate electrode layers 617 and 629 as masks, whereby first p-type impurity regions 660a, 660b, 663a, and 663b and second p-type impurity regions 661a, 661b, 664a, and 664b are formed.

In this embodiment mode, boron (B) is used as an impurity element; therefore, doping is conducted by using diborane (B₂H₆) as a doping gas containing an impurity element (the doping gas is obtained by diluting B₂H₆ with hydrogen (H₂); the percentage of B₂H₆ in the gas is 15%) under such conditions that the gas flow rate is 70 sccm, beam current is 180 μA/cm, acceleration voltage is 80 kV, and dosage is 2.0×10¹⁵ ions/cm². Here, doping is conducted such that each of the first p-type impurity regions 660a, 660b, 663a, and 663b, and the second p-type impurity regions 661a, 661b, 664a, and 664b contains the p-type impurity element at a concentration of about 1×10²⁰ to 5×10²¹/cm³.

In this embodiment mode, the second p-type impurity regions 661a, 661b, 664a, and 664b reflect the shapes of the gate electrode layers 617 and 629, and formed in a self-aligned manner so as to contain a lower concentration of impurities than the first p-type impurity regions 660a, 660b, 663a, and 663b. In addition, channel formation regions 662 and 665 are formed in the semiconductor layers 603 and 606, respectively.

The first p-type impurity regions 660a, 660b, 663a, and 663b are n-type high-concentration impurity regions and function as source regions or drain regions. On the other hand, the second p-type impurity regions 661a, 661b, 664a, and 664b are low-concentration impurity regions and function as LDD (Lightly Doped Drain) regions. The second p-type impurity regions 661a, 661b, 664a, and 664b that are covered with the first gate electrode layers 621 and 626 with the gate insulating layer 607 interposed therebetween are Lov regions, which can alleviate an electric field in the vicinity of the drain and can suppress hot-carrier degradation.

Then, the masks 655a and 655b are removed by O₂ ashing or with a resist stripper, whereby oxide films are also removed. After that, insulating films so-called sidewalls may be formed so as to cover the side surfaces of the gate electrode layers. The sidewalls may be formed by a plasma CVD method or a low-pressure CVD (LPCVD) method using an insulating film containing silicon.

In order to activate the impurity element, thermal treatment, strong light irradiation, or laser irradiation may further be conducted. In that case, the impurity element can be activated, while at the same time plasma damage to the gate insulating layer and plasma damage to the interface between the gate insulating layer and the semiconductor layers can be recovered.

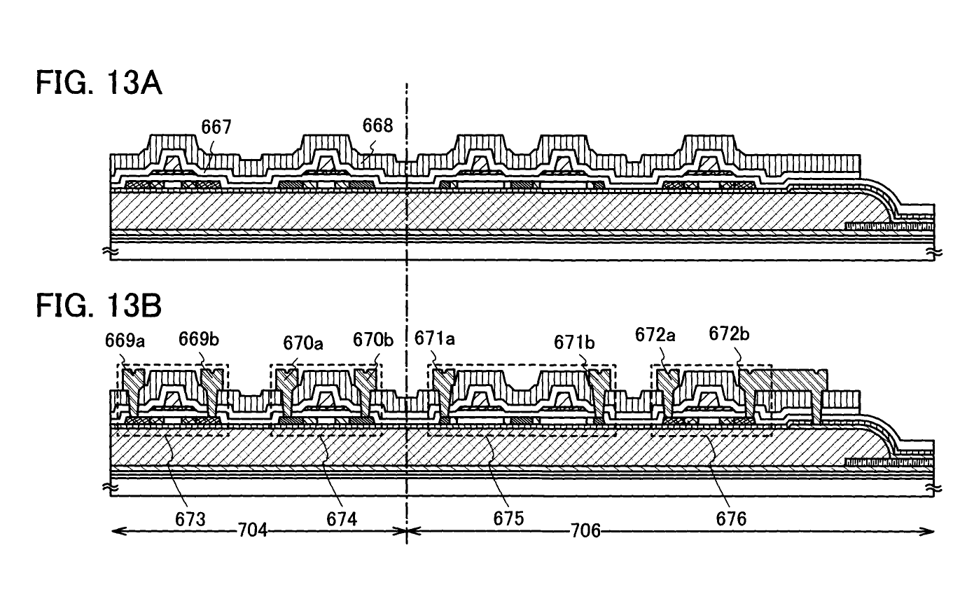

Next, an interlayer insulating layer which covers the gate electrode layers and the gate insulating layer is formed. In this embodiment mode, an insulating film 667 and an insulating film 668 are stacked (see FIG. 13A). Specifically, a stacked structure is formed by sequentially depositing a silicon nitride film containing oxygen to a thickness of 100 nm as the insulating film 667 and depositing a silicon oxide film containing nitrogen to a thickness of 900 nm as the insulating film 668. Alternatively, it is also possible to form a three-layer structure by sequentially depositing a silicon oxide film containing nitrogen to a thickness of 30 nm so as to cover the gate electrode layers and the gate insulating layer, depositing a silicon nitride film containing oxygen to a thickness of 140 nm, and depositing a silicon oxide film containing nitrogen to a thickness of 800 nm.

In this embodiment mode, the insulating films 667 and 668 are consecutively formed by a plasma CVD method similarly to the base films. Materials for forming the insulating films 667 and 668 are not limited to those described above. For example, a silicon nitride film, a silicon nitride film containing oxygen, a silicon oxide film containing nitrogen, and/or a silicon oxide film that are/is formed by a sputtering method or a plasma CVD method may also be employed. Further, it is also possible to use a single layer of another insulating film containing silicon, or a stacked structure of three or more layers of such insulating films.

As other materials for forming the insulating films 667 and 668, it is also possible to use a material selected from among aluminum nitride (AlN), aluminum oxide containing nitrogen (AlON) in which the weight of oxygen is greater than that of nitrogen, aluminum nitride containing oxygen (AlNO) in which the weight of nitrogen is greater than that of oxygen, aluminum oxide, diamond-like carbon (DLC), a carbon film containing nitrogen (CN), and other inorganic insulating materials.

Alternatively, a siloxane resin may also be used. Note that a siloxane resin corresponds to a resin having a Si—O—Si bond. Siloxane has a skeletal structure with the bond of silicon (Si) and oxygen (O). As a substituent of siloxane, an organic group containing at least hydrogen (e.g., an alkyl group or aromatic hydrocarbon) is used. Alternatively, a fluoro group may be used as the substituent. As a further alternative, both an organic group containing at least hydrogen and a fluoro group may be used as the substituent. Further, organic insulating materials can also be used. Examples of the organic materials include polyimide, acrylic, polyamide, polyimide amide, resist, benzocyclobutene, and polysilazane. It is also possible to use a highly flat film formed by a coating method.

Further, thermal treatment is applied at 300 to 550° C. for one to 12 hours in a nitrogen atmosphere, whereby a step of hydrogenating the semiconductor layers is conducted. Preferably, the thermal treatment is conducted at 400 to 500° C. This step is a step of saturating dangling bonds in the semiconductor layer by using hydrogen contained in the insulating film 667 which is the interlayer insulating layer. In this embodiment mode, the thermal treatment is conducted at 410° C. for one hour.

Next, contact holes (opening portions) that reach the semiconductor layers are formed in the insulating films 667 and 668 and the gate insulating layer 608, using a resist mask. In addition, a contact hole (opening portion) that reaches the second electrode layer 805 is formed in the insulating films 667 and 668, the gate insulating layer 607, and the first interlayer insulating layer 806. Etching may be conducted only once or a plurality of times depending on the etching selectivity of the materials used for the insulating films. In this embodiment mode, the first etching is conducted under such condition that the insulating film 668 which is a silicon oxide film containing nitrogen, the insulating film 667 which is a silicon nitride film containing oxygen, the gate insulating layer 607, and the first interlayer insulating layer 806 can have etching selectivity. Thus, the insulating film 668 is removed.

Next, the second etching is conducted in which the insulating film 667 and the gate insulating layer 607 are removed, whereby opening portions that reach the first p-type impurity regions 660a, 660b, 663a, and 663b and the second n-type impurity regions 644a, 644b, 647a, and 647b functioning as source regions or drain regions are formed.

In addition, the insulating film 667 and the first interlayer insulating layer 806 are also removed by the second etching, whereby an opening portion that reaches the electrode layer 805 is formed.

In this embodiment mode, the first etching is conducted by wet etching, and the second etching is conducted by dry etching. As an etchant of wet etching, it is preferable to use a solution containing fluorinated acid such as a mixed solution of ammonium hydrogenfluoride and ammonium fluoride. As an etching gas, a chlorine source gas typified by Cl₂, BCl₃, SiCl₄, or CCl₄; a fluorine source gas typified by CF₄, CF₅, SF₆, or NF₃; or O₂ can be used. Further, an inert gas may be mixed into the etching gas. As the inert gas element that is mixed, one or more elements selected from among He, Ne, Ar, Kr, and Xe can be used.

Then, a conductive film is formed so as to cover the opening portions, and the conductive film is etched. Thus, electrode layers 669a, 669b, 670a, 670b, 671a, 671b, 672a, and 672b which are source electrode layers connected to part of the respective source regions or drain electrode layers connected to part of the respective drain regions are formed. In addition, the electrode layer 672b which is a source electrode layer or a drain electrode layer is also electrically connected to the second electrode layer 805.

The source electrode layers or the drain electrode layers can be formed by the steps of depositing a conductive film by a PVD method, a CVD method, a vapor deposition method, or the like and etching the deposited conductive film into predetermined shapes. Alternatively, conductive layers can be selectively formed at predetermined positions by a droplet discharge method, a printing method, an electroplating method, or the like. Further, a reflow method or a damascene method can also be used. As materials for forming the source electrode layers or the drain electrode layers, metals such as Ag, Au, Cu, Ni, Pt, Pd, Ir, Rh, W, Al, Ta, Mo, Cd, Zn, Fe, Ti, Zr, and Ba, alloys thereof, or nitride thereof can be used. Further, a stacked structure of such materials can also be used.

In this embodiment mode, a stacked structure is formed by depositing a titanium (Ti) film to a thickness of 60 nm, depositing a titanium nitride film to a thickness of 40 nm, depositing an aluminum film to a thickness of 700 nm, and depositing a titanium (Ti) film to a thickness of 200 nm. Then, the layers are processed into desired shapes.

Though the above-described steps, thin film transistors (TFTs) are formed. Accordingly, an active matrix substrate can be fabricated which includes a p-channel thin film transistor 673 and an n-channel thin film transistor 674 in the peripheral driver circuit region 704, and also includes an n-channel thin film transistor 675 with a multi-channel structure and a p-channel thin film transistor 676 in the pixel region 706 (see FIG. 13B).

The structures of the thin film transistors are not limited to those shown in this embodiment mode. Any of a single-gate structure having one channel formation region, a double-gate structure having two channel formation regions, and a triple-gate structure having three channel formation regions may be employed. In addition, thin film transistors in the peripheral driver circuit region may also have any of a single-gate structure, a double-gate structure, and a triple-gate structure.

Note that a method of fabricating thin film transistors is not limited to that shown in this embodiment mode, and the invention can be similarly applied to other structures such as a top-gate (planar) structure, a bottom-gate (inversely staggered) structure, or a dual-gate structure that has two gate electrode layers above and below a channel formation region with gate insulating films interposed therebetween.

Next, a protective film 819 is formed covering the pixel region 706 and the peripheral driver circuit region 704. In this embodiment mode, the protective film 819 may have either a single-layer structure or a stacked structure. For example, a stacked structure of a silicon nitride oxide film with a thickness of 100 nm and a silicon oxynitride film with a thickness of 900 nm may be employed. Further, a stacked structure of three layers may also be employed.

In this embodiment mode, the stacked layers of the protective film 819 are consecutively formed by a plasma CVD method similarly to the base films. Materials for forming the protective film 819 are not limited to those described above. For example, a silicon nitride film, a silicon nitride oxide film, a silicon oxynitride film, and/or a silicon oxide film that are/is formed by a sputtering method or a plasma CVD method may also be employed. Further, it is also possible to use a single layer of another insulating film containing silicon, or a stacked structure of three or more layers of such insulating films.

As other materials for forming the protective film 819, it is also possible to use a material selected from among aluminum nitride (AlN), aluminum oxide containing nitrogen (AlON) in which the weight of oxygen is greater than that of nitrogen, aluminum nitride containing oxygen (AlNO) in which the weight of nitrogen is greater than that of oxygen, aluminum oxide, diamond-like carbon (DLC), a carbon film containing nitrogen (CN), and other inorganic insulating materials.

Alternatively, a siloxane resin may also be used. Note that a siloxane resin corresponds to a resin having a Si—O—Si bond. Siloxane has a skeletal structure with the bond of silicon (Si) and oxygen (O). As a substituent of siloxane, an organic group containing at least hydrogen (e.g., an alkyl group or aromatic hydrocarbon) is used. Alternatively, a fluoro group may be used as the substituent. As a further alternative, both an organic group containing at least hydrogen and a fluoro group may be used as the substituent. Further, organic insulating materials can also be used. Examples of the organic materials include polyimide, acrylic, polyamide, polyimide amide, resist, benzocyclobutene, and polysilazane. It is also possible to use a highly flat film formed by a coating method.

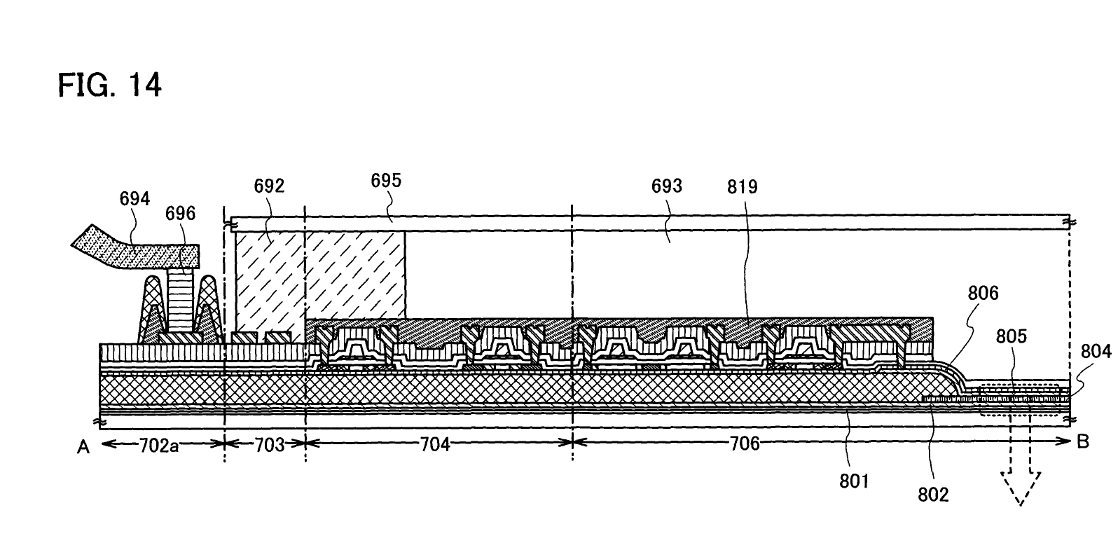

Next, the external terminal connection region 702b is covered with a resist mask having a predetermined opening portion, and the protective film 819 is etched (see FIG. 14).

Then, a sealing substrate 695 is attached to the TFT substrate with a sealant 692. A space 693 is filled with a filling material. As a filling material, an inert gas (e.g., nitrogen or argon) may be used or a sealant may also be used.

Note that the sealant 692 is preferably an epoxy resin. Further, such a material preferably allows as little moisture and oxygen as possible to penetrate. Further, the sealing substrate 695 may be formed using a glass substrate or a quartz substrate as well as a plastic substrate made of FRP (Fiber-Reinforced Plastics), PVF (PolyVinyl Fluoride), Mylar (registered trademark), polyester, or acrylic.

Through the above-described steps, a light-emitting device having the light-emitting element of the invention can be fabricated.

Note that the TFT may also be arranged in the same direction as the thickness direction of the light-emitting element, that is, arranged so as to overlap with the first electrode layer 802 or the second electrode layer 805 (see FIG. 15B). Such arrangement can reduce the area of the elements.

Since the light-emitting device of the invention includes thin film transistors (TFTs) and inorganic EL elements, it can be applied to an active matrix light-emitting device.

Further, since such a light-emitting device is free from defects such as hydrogen desorption from amorphous silicon or polysilicon used in the thin film transistors, an active matrix inorganic EL display without degraded characteristics of TFTs can be fabricated.

In addition, even a low-melting-point material such as aluminum and a low-heat-resistant material can be used for TFTs of an inorganic EL display. That is, the selection range of applicable materials is wide.

According to this embodiment mode, a light-emitting element which has increased luminance but has a reduced luminance decay rate over time can be provided as in Embodiment Mode 1. In particular, emission properties in the visible region can be stabilized. In addition, since the emission spectrum can be made broader and changed to an emission spectrum of a mixed color, such a light-emitting element can be used for various applications. Further, since light emission of a mixed color can be easily obtained, white light can be easily produced. Furthermore, since the luminance decay rate of the light-emitting element is low, a highly reliable light-emitting device can be provided.

Note that this embodiment mode can be combined with other embodiment modes as appropriate.

### Embodiment Mode 4

This embodiment mode will describe a light-emitting device having light-emitting elements fabricated by using the invention.

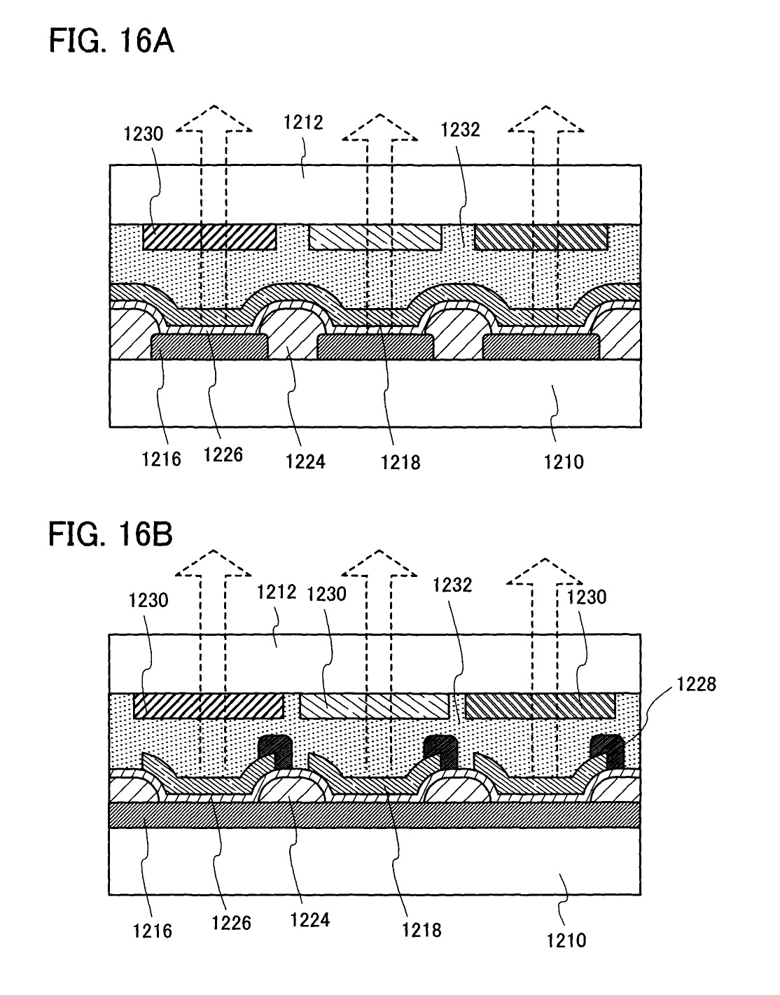

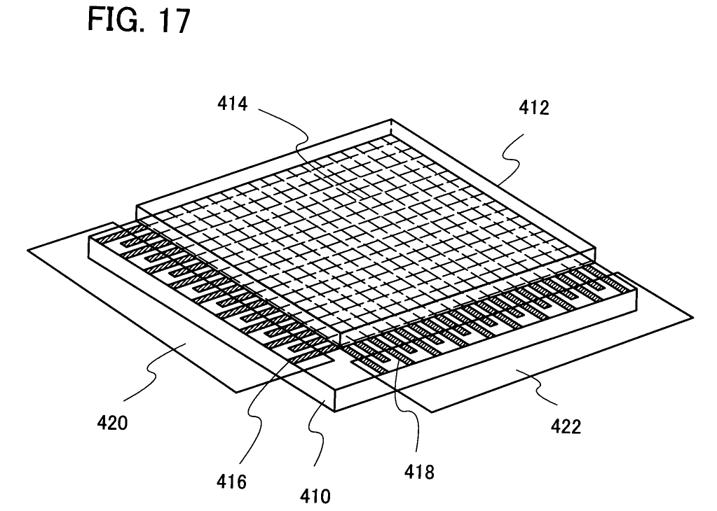

In this embodiment mode, a display device which is one aspect of a light-emitting device will be described, with reference to FIGS. 16A and 16B, FIG. 17, FIG. 18, FIG. 19, and FIGS. 20A, and 20B. FIG. 17 is a diagram showing the main configuration of a display device.

First electrodes 416 and second electrodes 418 which extend in a direction intersecting the first electrodes 416 are provided over a substrate 410. A light-emitting element having a light-emitting layer which is formed in a similar manner to those described in Embodiment Modes 1 to 3 is provided at each intersection of the first electrodes 416 and the second electrodes 418. In the display device shown in FIG. 17, a plurality of the first electrodes 416 and the second electrodes 418 are disposed, and a display portion 414 is constructed from a matrix arrangement of pixels each including a light-emitting element. The potentials of the first electrode 416 and the second electrode 418 are controlled to select emission/non-emission of the individual light-emitting elements, whereby moving images and still images can be displayed on the display portion 414.

In this display device, emission and non-emission of each light-emitting element is selected upon application of a signal indicative of a display image to each of the first electrode 416 which extends in one direction of the substrate 410 and the second electrode 418 which crosses the first electrode 416. That is, this display device is a passive matrix display device whose pixels are driven with signals that are supplied from external circuits. Such as display device has a simple configuration; therefore, it can be easily fabricated even when the display area is enlarged.

When both of the first electrode 416 and the second electrode 418 are formed using transparent conductive films, the light-emitting device in this embodiment mode can be completed as a dual emission light-emitting display device. Meanwhile, when one of the first electrode 416 and the second electrode 418 is formed using a reflective conductive film, the light-emitting device in this embodiment mode can be completed as a single emission (top-emission or bottom-emission) light-emitting device.

As examples of such transparent conductive films, the following can be used: indium tin oxide (ITO), ITO containing silicon oxide (ITSO), indium zinc oxide (IZO), indium oxide containing tungsten oxide and zinc oxide (IWZO), and the like. Meanwhile, as examples of reflective conductive films, the following can be used: aluminum (Al), silver (Ag), gold (Au), platinum (Pt), nickel (Ni), tungsten (W), chromium (Cr), molybdenum (Mo), iron (Fe), cobalt (Co), copper (Cu), palladium (Pd), nitride of metal materials (e.g., titanium nitride: TiN), and the like.

Note that a counter substrate 412 may be provided as required. The counter substrate 412 can also function as a protective member when it is provided to adequately overlap with the display portion 414. Not only a plate-form hard material, but also a resin film or a resin coating material can be used for the counter substrate 412. The first electrodes 416 and the second electrodes 418 are led out to the edge of the substrate 410, forming terminals connected to external circuits. That is, the first electrodes 416 and the second electrodes 418 form a contact with first and second flexible substrates 420 and 422, respectively. Examples of the external circuits include a controller circuit for controlling video signals, a power supply circuit, a tuner circuit, and the like.

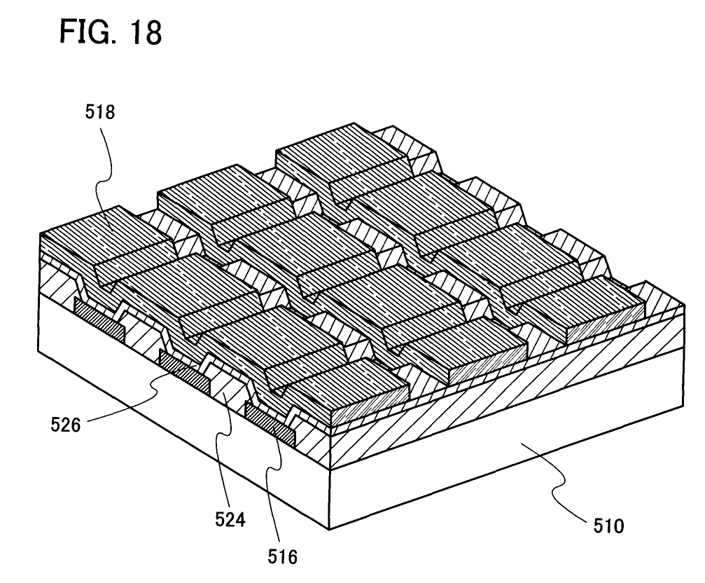

FIG. 18 is a partial enlarged view showing the configuration of the display portion 414 in FIG. 17. Partition layers 524 are formed on opposite side edges of each first electrode 516. In addition, at least a light-emitting layer (also referred to as an EL layer) 526 is formed over an exposed surface of the first electrode 516. A second electrode 518 is formed over the EL layer 526. Since the second electrode 518 crosses the first electrode 516, it is provided in a manner extending over the partition layer 524. The partition layer 524 is formed from an insulating material so as to prevent short circuit between the first electrode 516 and the second electrode 518. The side edge of the partition layer 524 slopes and has a so-called tapered shape so that a portion of the partition layer 524 which covers the edge of the first electrode 516 does not have a steep step. When the partition layer 524 is formed to have such a shape, it can adequately cover the first electrode 516, whereby defects such as cracks and breaking can be prevented.

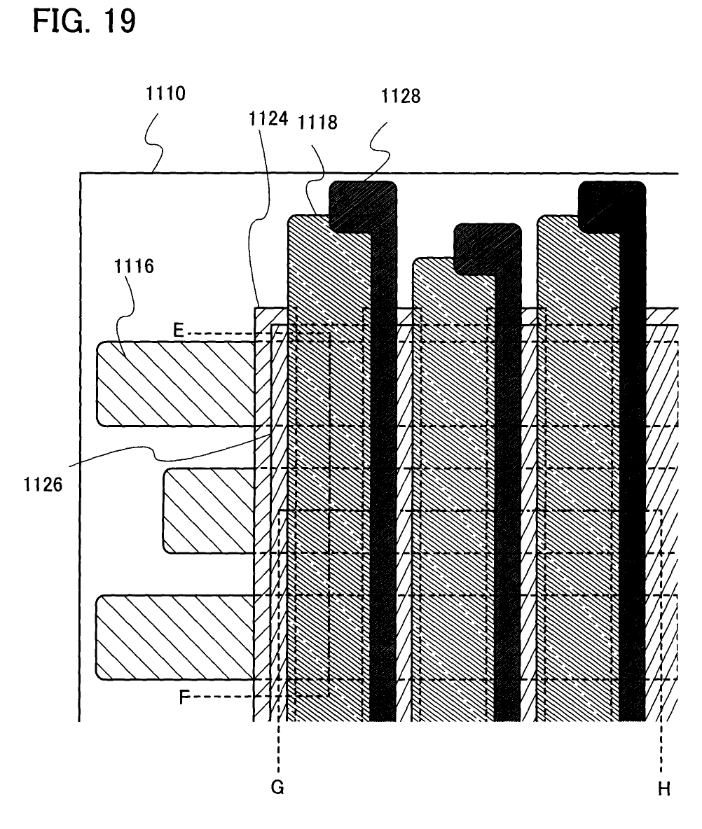

FIG. 19 is a plan view of the display portion 414 in FIG. 17, which shows the arrangement of a first electrode 1116, a second electrode 1118, a partition layer 1124, and an EL layer 1126 over a substrate 1110. When the second electrode 1118 is formed using a transparent conductive film such as indium tin oxide or zinc oxide, an auxiliary electrode 1128 is preferably provided in order to reduce resistance loss. In that case, the auxiliary electrode 1128 is preferably formed with a high-melting-point metal such as titanium, tungsten, chromium, or tantalum, or with a combination of such a high-melting-point metal and a low-resistance metal such as aluminum and silver.

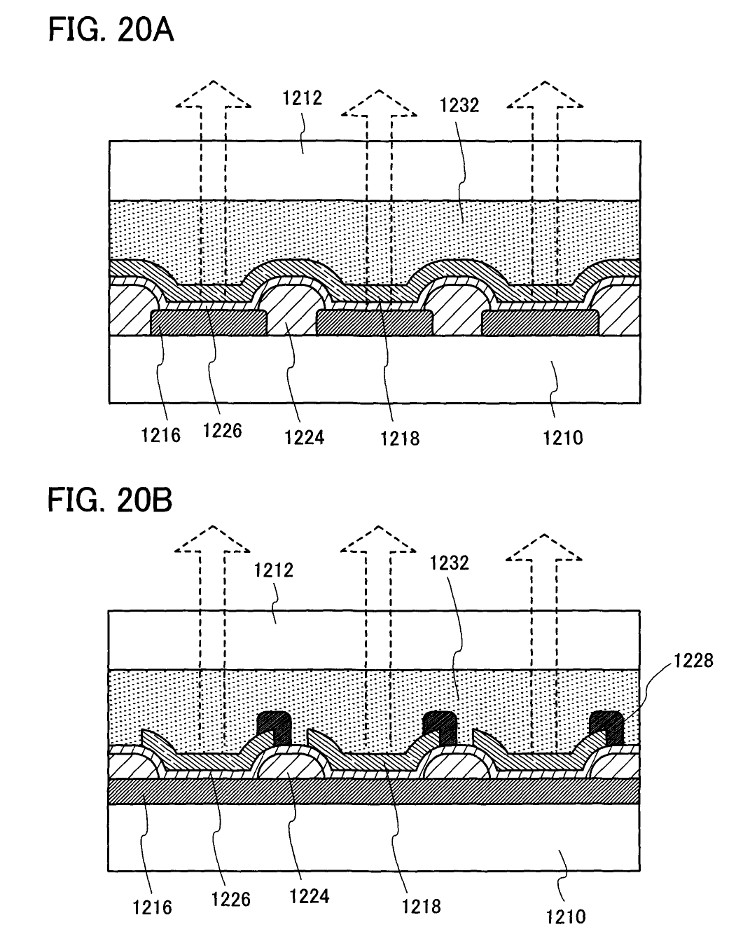

FIGS. 20A and 20B are cross-sectional views taken along lines E-F and G-H in FIG. 19, respectively. FIG. 20A is a cross-sectional view in which the first electrodes 416 in FIG. 17 are arranged. FIG. 20B is a cross-sectional view in which the second electrodes 418 in FIG. 17 are arranged. An EL layer 1226 is formed at the intersection of a first electrode 1216 and a second electrode 1218 over a substrate 1210, and a light-emitting element is formed in that portion. As shown in FIG. 20B, an auxiliary electrode 1228 is provided over a partition layer 1224 so as to be in contact with the second electrode 1218. When the auxiliary electrode 1228 is provided over the partition layer 1224, light emitted from the light-emitting element provided at the intersection of the first electrode 1216 and the second electrode 1218 is not blocked. Therefore, the light emission can be effectively utilized. In addition, the auxiliary electrode 1228 can be prevented from being short-circuited to the first electrode 1216.

FIGS. 16A and 16B show examples where color conversion layers 1230 are provided on a counter substrate 1212 of the light-emitting device shown in FIGS. 20A and 20B. The color conversion layers 1230 have a function of converting the wavelength of light emitted from the EL layers 1226, thereby changing the emission color. In this case, light emitted from the EL layers 1216 is preferably blue light which has high energy or ultraviolet light. When color conversion layers which convert light into red, green, and blue colors are arranged as the color conversion layers 1230, a display device which performs RGB color display can be formed. Alternatively, the color conversion layers 1230 can be replaced with colored layers (color filters). In that case, the EL layers 1216 are acceptable as long as they are formed to emit white light. The filling material 1232 has a function of securing the substrate 1210 and the counter substrate 1212 in position and may be provided as appropriate.

The light-emitting device of the invention can easily obtain light of a mixed color; therefore, white light can be easily produced. Further, since the luminance decay rate of the light-emitting element is low, a highly reliable light-emitting device can be provided.

Note that this embodiment mode can be combined with other embodiment modes as appropriate.

### Embodiment Mode 5

This embodiment mode will describe electronic apparatuses of the invention which include the light-emitting devices shown in Embodiment Modes 1 to 3. The electronic apparatuses of the invention include the light-emitting elements shown in Embodiment Modes 1 to 3. With the light-emitting elements having reduced driving voltage and high luminance, electronic devices having reduced power consumption and high luminance can be provided.

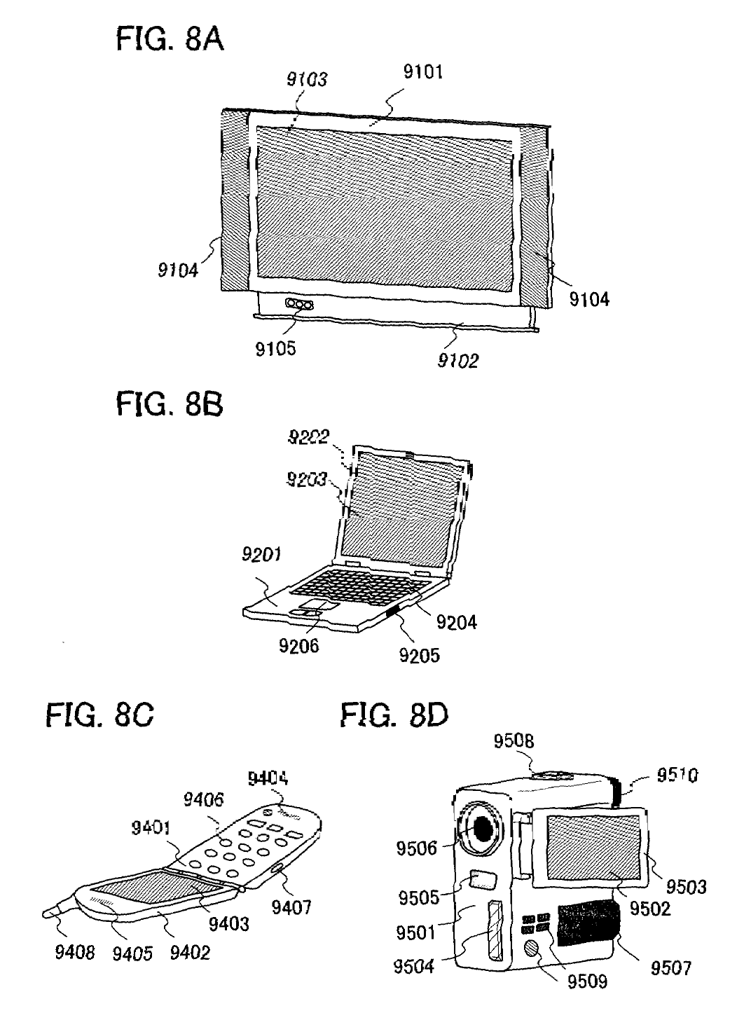

Examples of electronic apparatuses formed using the light-emitting device of the invention include: video cameras, digital cameras, goggle displays, navigation systems, audio reproducing devices (e.g., car audio component stereos and audio component stereos), computers, game machines, portable information terminals (e.g., mobile computers, mobile phones, portable game machines, and electronic books), and image reproducing devices provided with recording media (specifically, a device capable of reproducing the content of a recording medium such as a digital versatile disc (DVD) and provided with a display device that can display the reproduced image), and the like. Specific examples of such electronic devices are shown in FIGS. 8A to 8D.

FIG. 8A shows a television set in accordance with the invention, which includes a housing 9101, a supporting base 9102, a display portion 9103, speaker portions 9104, video input terminals 9105, and the like. In this television set, the display portion 9103 has a matrix arrangement of light-emitting elements similar to those shown in Embodiment Modes 1 to 3.

The light-emitting elements formed in accordance with the invention can easily obtain white light, and have a feature of a low luminance decay rate. Accordingly, the display device of the invention has advantages in low cost and high reliability. The display portion 9103 having such light-emitting elements has similar features; therefore, this television set requires low production cost and has high reliability.

FIG. 8B shows a computer in accordance with the invention, which includes a main body 9201, a housing 9202, a display portion 9203, a keyboard 9204, an external connection port 9205, a pointing device 9206, and the like. In this computer, the display portion 9203 has a matrix arrangement of light-emitting elements similar to those shown in Embodiment Modes 1 to 3.

The light-emitting elements formed in accordance with the invention can easily obtain white light, and have a feature of a low luminance decay rate. Accordingly, the display device of the invention has advantages in low cost and high reliability. The display portion 9203 having such light-emitting elements has similar features; therefore, this computer requires low production cost and has high reliability.

FIG. 8C shows a mobile phone in accordance with the invention, which includes a main body 9401, a housing 9402, a display portion 9403, an audio input portion 9404, an audio output portion 9405, operation keys 9406, an external connection port 9407, an antenna 9408, and the like. In this mobile phone, the display portion 9403 has a matrix arrangement of light-emitting elements similar to those shown in Embodiment Modes 1 to 3.

The light-emitting elements formed in accordance with the invention can easily obtain white light, and have a feature of a low luminance decay rate. Accordingly, the display device of the invention has advantages in low cost and high reliability. The display portion 9403 having such light-emitting elements has similar features; therefore, this mobile phone requires low production cost and has high reliability.

FIG. 8D shows a camera in accordance with the invention, which includes a main body 9501, a display portion 9502, a housing 9503, an external connection port 9504, a remote controller receiving portion 9505, a image receiving portion 9506, a battery 9507, an audio input portion 9508, operation keys 9509, an eyepiece portion 9510, and the like. In this camera, the display portion 9502 has a matrix arrangement of light-emitting elements similar to those shown in Embodiment Modes 1 to 3.

The light-emitting elements formed in accordance with the invention can easily obtain white light, and have a feature of a low luminance decay rate. Accordingly, the display device of the invention has advantages in low cost and high reliability. The display portion 9502 having such light-emitting elements has similar features; therefore, this camera requires low production cost and has high reliability.

As described above, the applicable range of the light-emitting device of the invention is so wide that the light-emitting device can be applied to electronic devices in various fields. By using the light-emitting device of the invention, an electronic device having a highly reliable display portion which requires low production cost and has a low luminance decay rate can be provided.

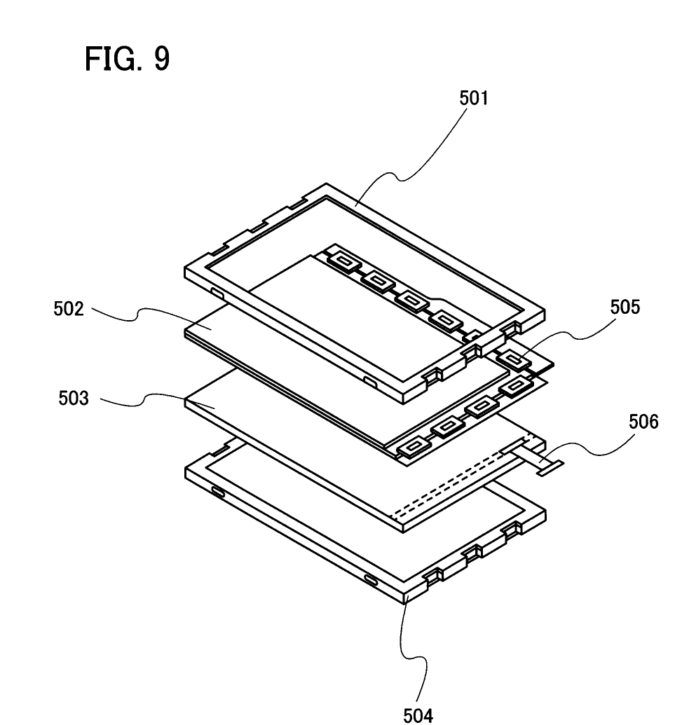

Further, since the light-emitting device of the invention has light-emitting elements with high luminous efficiency, it can also be used as a lighting device. An example of using the light-emitting elements of the invention for a lighting device will be described with reference to FIG. 9.

FIG. 9 shows an example of a liquid crystal display device which uses the light-emitting device of the invention as a backlight. The liquid crystal display device shown in FIG. 9 includes a housing 501, a liquid crystal layer 502, a backlight 503, and a housing 504, and the liquid crystal layer 502 is connected to a driver IC 505. The light-emitting device of the invention is used for the backlight 503, and current is supplied through a terminal 506.

By using the light-emitting device of the invention as a backlight of a liquid crystal display device, a highly reliable backlight which requires low production cost and has a low luminance decay rate can be obtained. Further, the light-emitting device of the invention is a lighting device with plane emission and can have a large area. Therefore, the backlight can have a large area, and a liquid crystal display device having a large area can be obtained. Furthermore, the light-emitting device of the invention has a thin shape and has low power consumption; therefore, a thin shape and low power consumption of a display device can also be achieved.

The present application is based on Japanese Priority application No. 2006-193289 filed on Jul. 13, 2006 with the Japanese Patent Office, the entire contents of which are hereby incorporated by reference.

What is claimed is:

1. A light-emitting element comprising a light-emitting layer, wherein the light-emitting layer contains zinc sulfide and manganese;
wherein an emission spectrum of the light-emitting layer is distributed in a wavelength range of 500 nm to 700 nm; and
wherein the emission spectrum includes a first peak having a shorter wavelength than 580 nm and a second peak having a longer wavelength than 580 nm.

2. The light-emitting element according to claim 1,
wherein the manganese is a luminescence center of the light-emitting layer.

3. The light-emitting element according to claim 1,
wherein the light-emitting layer has a crystal structure that a base material of the light-emitting layer is the zinc sulfide, and
wherein zinc of the zinc sulfide is partially substituted by the manganese.

4. The light-emitting element according to claim 3,
wherein the crystal structure is a cubic crystal structure, and
wherein the crystal structure has a distortion of a crystal lattice.

5. A light-emitting device comprising a light-emitting element and a driver circuit for controlling an emission of the light-emitting element,
wherein the light-emitting element includes a light-emitting layer containing zinc sulfide and manganese;
wherein an emission spectrum of the light-emitting layer is distributed in a wavelength range of 500 nm to 700 nm; and
wherein the emission spectrum includes a first peak having a shorter wavelength than 580 nm and a second peak having a longer wavelength than 580 nm.

6. The light-emitting device according to claim 5,
wherein the manganese is a luminescence center of the light-emitting layer.

7. The light-emitting device according to claim 5,
wherein the light-emitting layer has a crystal structure that a base material of the light-emitting layer is the zinc sulfide, and
wherein zinc of the zinc sulfide is partially substituted by the manganese.

8. The light-emitting device according to claim 7,
wherein the crystal structure is a cubic crystal structure, and
wherein the crystal structure has a distortion of a crystal lattice.

9. A method of fabricating a light-emitting element, comprising the steps of:
forming a light-emitting layer which contains zinc sulfide and manganese and has an emission spectrum with one emission peak in a range of 500 nm to 700 nm; and
applying thermal treatment to the light-emitting layer so that the emission spectrum with one emission peak is divided into a first peak having a shorter wavelength than 580 nm and a second peak having a longer wavelength than 580 nm.

10. The method of fabricating a light-emitting element according to claim 9,
wherein the thermal treatment is conducted within a range of 500° C. to 800° C.

11. A method of fabricating a light-emitting element, comprising the steps of:
forming a first electrode over a substrate;
forming a first dielectric layer over the first electrode;
forming a light-emitting layer which contains zinc sulfide and manganese and has an emission spectrum with one emission peak in a range of 500 nm to 700 nm;
forming a second dielectric layer over the light-emitting layer;
applying thermal treatment to the light-emitting layer so that the emission spectrum with one emission peak is divided into a first peak having a shorter wavelength than 580 nm and a second peak having a longer wavelength than 580 nm; and
forming a second electrode over the second dielectric layer.

12. The method of fabricating a light-emitting element according to claim 11,
wherein the thermal treatment is conducted within a range of 500° C. to 800° C.

13. The method of fabricating a light-emitting element according to claim 11,
wherein a thickness of the first electrode or the second electrode is from 1 nm to 50 nm.
